(19) United States
(12) Patent Application Publication
(10) Pub. No.: US 2012/0119196 A1
(43) Pub. Date: May 17, 2012

(54) ORGANIC ELECTROLUMINESCENT ELEMENT

(75) Inventors: Toshinari Ogiwara, Chiba (JP); Toshihiro Iwakuma, Chiba (JP); Mitsunori Ito, Chiba (JP)

(73) Assignee: IDEMITSU KOSAN CO., LTD., Chiyoda-ku, Tokyo (JP)

(21) Appl. No.: 13/386,766

(22) PCT Filed: Sep. 8, 2010
(86) PCT No.: PCT/JP2010/065444

§ 371 Date: Jan. 24, 2012

(30) Foreign Application Priority Data
Sep. 17, 2009 (JP) 2009-216051

(51) Int. Cl. H01L 51/54

(52) U.S. Cl. 257/40; 257/E51.026

(57) ABSTRACT

An organic electroluminescence device includes a cathode, an anode, and a single-layered or multilayered organic thin-film layer provided between the cathode and the anode. The organic thin-film layer contains an organic compound represented by a formula (1) below and a phosphorescent material. The triplet energy Eg(T) of the organic compound represented by the formula (1) is larger than that of the phosphorescent material.

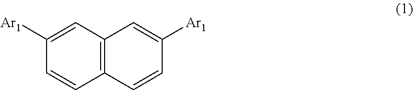

In the formula (1), Ar₁ is a fused aromatic hydrocarbon ring which may have a substituent and is selected from a benzophenanthrene ring, dibenzophenanthrene ring, chrysene ring, benzochrysene ring, dibenzochrysene ring and the like. The substituent is a halogen atom, alkoxy group, aryloxy group, cyano group, arylsilyl group, alkylsilyl group, alkylarylsilyl group, heterocyclic group or the like.

### TECHNICAL FIELD

The present invention relates to an organic electroluminescence device. In particular, the present invention relates to an organic electroluminescence device including a red-phosphorescent-emitting layer.

### BACKGROUND ART

A known organic electroluminescence device includes an organic thin-film layer between an anode and a cathode, the organic thin-film layer including an emitting layer, and emits light using exciton energy generated by a recombination of holes and electrons injected into the emitting layer (see Patent Literatures 1 to 6).

Such an organic electroluminescence device, which has the advantages as a self-emitting device, is expected to serve as an emitting device excellent in luminous efficiency, image quality, power consumption and thin design.

An example of a further improvement made in an organic electroluminescence device is an improvement in luminous efficiency.

In this respect, in order to enhance internal quantum efficiency, developments have been made on a luminescent material (phosphorescent material) that emits light using triplet excitons. In recent years, there has been a report on a phosphorescent organic electroluminescence device.

Since the internal quantum efficiency can be enhanced up to 75% or more (up to approximately 100% in theory) by forming the emitting layer (phosphorescent-emitting layer) from such a phosphorescent material, an organic electroluminescence device having high efficiency and consuming less power can be obtained.

In forming the emitting layer, a doping method, according to which a luminescent material (dopant) is doped to a host, has been known as a usable method.

The emitting layer formed by the doping method can efficiently generate excitons from electric charges injected into the host. With the exciton energy generated by the excitons being transferred to the dopant, the dopant can emit light with high efficiency.

In order to intermolecularly transfer the energy from the host to a phosphorescent dopant, triplet energy Eg_{H}(T) of the host is required to be larger than triplet energy Eg_{D}(T) of the phosphorescent dopant.

A known representative example of a material having effectively large triplet energy has been CBP (4,4′-bis(N-carbazolyl)biphenyl). See, for instance, Patent Literature 1.

By using such CBP as the host, energy can be transferred to the phosphorescent dopant for emitting light of a predetermined emission wavelength (e.g., green, red), by which an organic electroluminescence device of high efficiency can be obtained.

Alternatively, Patent Literature 2 discloses a technique according to which a fused-ring derivative containing a nitrogen-containing ring such as carbazole is used as the host for a red-phosphorescent-emitting layer.

On the other hand, a variety of hosts (fluorescent hosts) for fluorescent-emitting layers that generate fluorescent emission are known. Various proposals have been made on hosts capable of, with a combination of a fluorescent dopant, providing a fluorescent-emitting layer excellent in luminous efficiency and lifetime.

Generally, even a fluorescent host material effective in fluorescent emission is different in physical properties from a fluorescent device (physical properties are an important factor for designing a phosphorescent device). In particular, since triplet energy Eg(T) of a fluorescent host material is not sufficiently large to be suitable for a phosphorescent device, usability as a fluorescent host is not important in selecting a phosphorescent host material.

A well-known example of a fluorescent host is an anthracene derivative.

However, triplet energy Eg(T) of an anthracene derivative is relatively small (approximately 1.8 eV). Thus, energy cannot be reliably transferred to a phosphorescent dopant for emitting light having an emission wavelength in a visible light range of 600 nm to 720 nm. In addition, excited triplet energy cannot be trapped within the emitting layer.

Accordingly, an anthracene derivative is not suitable for the phosphorescent host.

Further, derivatives such as a perylene derivative and a pyrene derivative are not preferable phosphorescent hosts for the same reason above.

An exemplary arrangement in which an aromatic hydrocarbon compound is used as the phosphorescent host has been known (Patent Literature 3). In the arrangement disclosed in Patent Literature 3, a compound in which two aromatic groups are bonded as substituents to a benzene central skeleton in meta positions is used as the phosphorescent host.

Patent Literature 4 exemplarily teaches compounds in which aromatic substituents of which essential skeletons are anthracene rings are arranged at right and left substituent positions of 2,7-naphthalene rings. Such compounds are used as hosts for blue emission, or are luminescent materials capable of emitting blue light by themselves.

Additionally, Patent Literature 5 discloses compounds in which four or more of the same aromatic hydrocarbon rings are continuously coupled to one another at right and left substituent positions of 2,7-naphthalene rings, and organic electroluminescence devices using the compounds.

Patent Literature 6 discloses organic electroluminescence devices in which various dibenzofuran compounds are used. Patent Literature 6 discloses compounds in which four or more of the same aromatic hydrocarbon rings are continuously coupled to one another at right and left substituent positions of 2,8-dibenzofuran rings.

### CITATION LIST

### Patent Literatures

Patent Literature 1: US2002/0182441

Patent Literature 2: W02005/112519

Patent Literature 3: JP-A-2003-142267

Patent Literature 4: JP-A-2006-045503

Patent Literature 5: JP-A-2008-255099

Patent Literature 6: W02006/128800

### SUMMARY OF THE INVENTION

### Problems to be Solved by the Invention

However, when applied with CBP as the host, the organic electroluminescence device disclosed in Patent Literature 1 exhibits much higher luminous efficiency due to phosphorescent emission on one hand, but exhibits such a short lifetime as to be practically unusable on the other hand. Such a problem is considered to be attributed to considerable degradation of molecules by holes due to not-high oxidation stability that the molecular structure of CBP exhibits.

Although the organic electroluminescence device disclosed in Patent Literature 2 exhibits improvement in the luminous efficiency and lifetime, the improved luminous efficiency and lifetime is not sufficient for practical application.

The aromatic hydrocarbon compound disclosed in Patent Literature 3 is molecularly structured such that the molecules extend from the benzene central skeleton in a manner symmetrical relative to the benzene central skeleton. Therefore, an emitting layer applied with the aromatic hydrocarbon compound tends to be easily crystallized. Accordingly, an organic electroluminescence device in which the aromatic hydrocarbon compound disclosed in Patent Literature 3 is used may require a higher driving voltage, which results in a shorter lifetime of the organic electroluminescence device.

Patent Literature 4 lacks sufficient studies of a relationship between the triplet energy of the exemplary aromatic hydrocarbon compound and the triplet energy of the phosphorescent dopant, and is silent on how efficiently the aromatic hydrocarbon compound useful for phosphorescence emission with high internal quantum efficiency is used as the phosphorescent host. Patent Literature 4 merely discloses luminous efficiency or lifetime in relation to the performance of an organic electroluminescence device, and fails to disclose an organic electroluminescence device with sufficient luminous efficiency and lifetime.

Patent Literature 5 discloses the effectiveness of the exemplary aromatic hydrocarbon compound used as the fluorescent host and Patent Literature 6 discloses the effectiveness of the exemplary dibenzofuran compound used as the fluorescent host. However, Patent Literatures 5 and 6 are silent on the effectiveness of these compounds as a phosphorescent material useful for phosphorescence emission with high internal quantum efficiency, in particular, on an improvement in the luminous efficiency and lifetime of the phosphorescent device.

An object of the invention is to provide an organic electroluminescence device with high efficiency and long lifetime.

### Means for Solving the Problems

Through concentrated studies in order to achieve such an object, the inventors have found out that an organic electroluminescence device exhibits higher efficiency and longer lifetime by using as a phosphorescent device an organic compound selected from an arrangement represented by the following formula (1) and an arrangement represented by the following formula (2), and have reached the invention.

According to an aspect of the invention, an organic electroluminescence device includes: a cathode; an anode; and a single-layered or multilayered organic thin-film layer provided between the cathode and the anode, in which at least one of layer(s) forming the organic thin-film layer includes an organic compound represented by a formula (1) or (2) below, at least one of layer(s) forming the organic thin-film layer comprises a phosphorescent material, and a triplet energy Eg(T) of the organic compound represented by the formula (1) or (2) is larger than a triplet energy Eg(T) of the phosphorescent material.

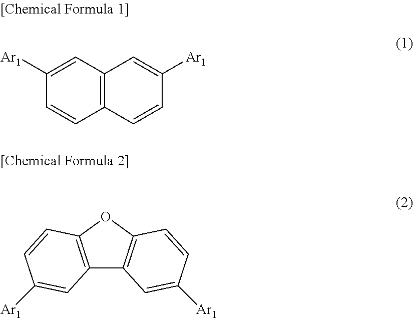

In the formula (1) or (2), Arᵢ is a fused aromatic hydrocarbon ring which may have a substituent and is selected from a benzophenanthrene ring, dibenzophenanthrene ring, chrysene ring, benzochrysene ring, dibenzochrysene ring, fluoranthene ring, benzofluoranthene ring, triphenylene ring, benzotriphenylene ring, dibenzotriphenylene ring, picene ring, benzopicene ring and dibenzopicene ring.

The substituent is a halogen atom, alkoxy group, aryloxy group, cyano group, arylsilyl group, alkylsilyl group, alkylarylsilyl group, alkyl group, haloalkyl group, arylamino group or heterocyclic group.

When the organic thin-film layer of the organic electroluminescence device is provided by a plurality of layers, the organic compound represented by the formula (1) or (2) and the phosphorescent material may be contained in the same layer or in different layers, or may be contained together in plural layers. Examples of the organic thin-film layer include an emitting layer, a hole injecting layer, a hole transporting layer, an electron injecting layer, an electron transporting layer, a hole blocking layer and electron blocking layer. In the above aspect of the invention, the An is preferably one of a benzo[c]phenanthrene ring which may have the substituent and a benzo[g]chrysene ring which may have the substituent.

In the above aspect of the invention, the Arᵢ is preferably one of a 5-benzo[c]phenanthrenyl group which may have the substituent, a 6-benzo[c]phenanthrenyl group which may have the substituent and a 10-benzo[g]chrysenyl group which may have the substituent.

In the above aspect of the invention, the triplet energy Eg(T) of the organic compound represented by the formula (1) or (2) is preferably in a range of 2.2 eV to 2.7 eV.

In the above aspect of the invention, at least one of layer(s) forming the organic thin-film layer preferably includes the organic compound represented by the formula (1) or (2) and the phosphorescent material.

In the above aspect of the invention, at least one of layer(s) forming the organic thin-film layer preferably functions as an emitting layer.

In the above aspect of the invention, the phosphorescent material preferably contains a metal complex, and the metal complex preferably has a metal atom selected from Ir, Pt, Os, Au, Re and Ru, and a ligand. Ir represents iridium, Pt represents platinum, Os represents osmium, Au represents gold, Re represents rhenium, and Ru represents ruthenium.

In the above aspect of the invention, the metal complex preferably has an ortho-metal bond of the ligand and the metal atom.

In the above aspect of the invention, at least one of the phosphorescent material contained in the organic thin-film layer preferably emits light having a maximum emission wavelength of 600 nm to 720 nm.

In the above aspect of the invention, at least one of an electron transporting layer and an electron injecting layer is preferably provided between the cathode and the emitting layer, and the electron transporting layer or the electron injecting layer preferably includes a heterocyclic compound having a nitrogen-containing six-membered or five-membered ring skeleton.

In the above aspect of the invention, a reduction-causing dopant is preferably present at an interfacial region between the cathode and the organic thin-film layer.

The organic electroluminescence device according to the above aspect of the invention is a device having an organic compound and an emitting layer containing a phosphorescent material (iridium complex or the like), the organic compound having a 2,7-naphthalene ring or a 2,8-dibenzofuran ring provided at the center of a molecular frame and aromatic hydrocarbon rings such as a benzophenanthrene ring and a benzochrysene ring provided at both terminals of the 2,7-naphthalene ring or the 2,8-dibenzofuran ring. The inventors have first found out that a phosphorescent organic electroluminescence device having the above arrangement exhibits high efficiency and long lifetime.

### Effects of the Invention

According to the invention, an organic compound represented by the above formula (1) or (2) is used to provide a phosphorescent organic electroluminescence device having high efficiency and long lifetime.

### BRIEF DESCRIPTION OF DRAWING

FIG. 1 schematically shows an exemplary arrangement of an organic electroluminescence device according to an exemplary embodiment of the invention.

### DESCRIPTION OF EMBODIMENT

An embodiment of the invention will be described below.

Arrangement of Organic Electroluminescence Device

Description will be made on an arrangement of an organic electroluminescence device (hereinafter occasionally abbreviated as an “organic EL device”) according to an exemplary embodiment of the invention.

The following are representative arrangement examples of the organic EL device:

(1) anode/emitting layer/cathode;

(2) anode/hole injecting layer/emitting layer/cathode;

(3) anode/emitting layer/electron injecting·transporting layer/cathode;

(4) anode/hole injecting layer/emitting layer/electron injecting·transporting layer/cathode;

(5) anode/organic semiconductor layer/emitting layer/cathode;

(6) anode/organic semiconductor layer/electron blocking layer/emitting layer/cathode;

(7) anode/organic semiconductor layer/emitting layer/adhesion improving layer/cathode;

(8) anode/hole injecting·transporting layer/emitting layer/electron injecting·transporting layer/cathode;

(9) anode/insulating layer/emitting layer/insulating layer/cathode;

(10) anode/inorganic semiconductor layer/insulating layer/emitting layer/insulating layer/cathode;

(11) anode/organic semiconductor layer/insulating layer/emitting layer/insulating layer/cathode;

(12) anode/insulating layer/hole injecting·transporting layer/emitting layer/insulating layer/cathode; and

(13) anode/insulating layer/hole injecting·transporting layer/emitting layer/electron injecting·transporting layer/cathode.

While the arrangement (8) is preferably used among the above, the arrangement of the invention is not limited to the above arrangements.

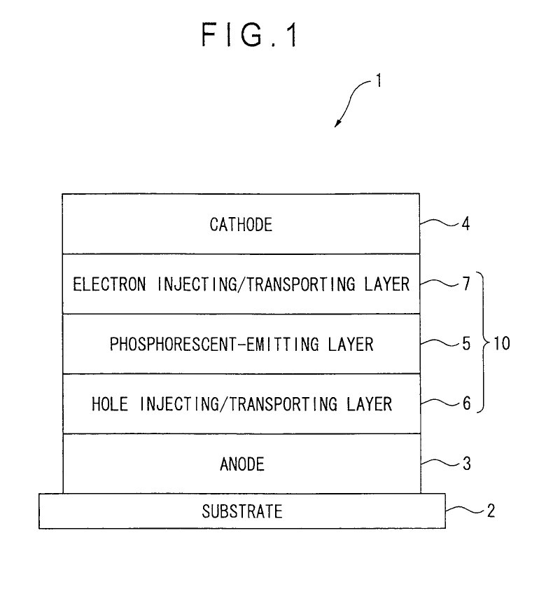

FIG. 1 schematically shows an exemplary arrangement of an organic EL device according to this exemplary embodiment of the invention.

An organic EL device 1 includes a transparent substrate 2, an anode 3, a cathode 4 and an organic thin-film layer 10 provided between the anode 3 and the cathode 4.

The organic thin-film layer 10 includes a phosphorescent-emitting 5 containing phosphorescent host and phosphorescent dopant. A layer such as a hole injecting/transporting layer 6 may be provided between the phosphorescent-emitting layer 5 and the anode 3 while a layer such as an electron injecting/transporting layer 7 may be provided between the phosphorescent-emitting layer 5 and the cathode 4.

In addition, an electron blocking layer may be provided to the phosphorescent-emitting layer 5 adjacently to the anode 3 while a hole blocking layer may be provided to the phosphorescent-emitting layer 5 adjacently to the cathode 4.

With this arrangement, electrons and holes can be trapped in the phosphorescent-emitting layer 5, thereby enhancing probability of exciton generation in the phosphorescent-emitting layer 5.

It should be noted that a “fluorescent host” and a “phosphorescent host” herein respectively mean a host combined with a fluorescent dopant and a host combined with a phosphorescent dopant, and that a distinction between the fluorescent host and the phosphorescent host is not unambiguously derived only from a molecular structure of the host in a limited manner.

It should also be noted that the “hole injecting/transporting layer (or hole injecting·transporting layer)” herein means “at least one of hole injecting layer and hole transporting layer” while “electron injecting/transporting layer (or electron injecting·transporting layer)” herein means “at least one of electron injecting layer and electron transporting layer”.

Light-Transmissive Substrate

The organic EL device according to the exemplary embodiment of the invention is formed on a light-transmissive substrate. The light-transmissive substrate, which supports the organic EL device, is preferably a smoothly-shaped substrate that transmits 50% or more of light in a visible region of 400 nm to 700 nm.

The light-transmissive substrate is exemplarily a glass plate, a polymer plate or the like.

For the glass plate, materials such as soda-lime glass, barium/strontium-containing glass, lead glass, aluminosilicate glass, borosilicate glass, barium borosilicate glass and quartz are usable.

For the polymer plate, materials such as polycarbonate resins, acryl resins, polyethylene terephthalate resins, polyether sulfide resins and polysulfone resins are usable.

Anode and Cathode

The anode of the organic EL device is used for injecting holes into the hole injecting layer, the hole transporting layer or the emitting layer. It is effective that the anode has a work function of 4.5 eV or more.

Exemplary materials for the anode are alloys of indium-tin oxide (ITO), tin oxide (NESA), indium zinc oxide, gold, silver, platinum and copper.

The anode may be made by forming a thin film from the above electrode materials through a method such as vapor deposition or sputtering.

When light from the emitting layer is to be emitted through the anode as in this exemplary embodiment, the anode preferably transmits more than 10% of the light in the visible region. Sheet resistance of the anode is preferably several hundreds CV square or lower. Although depending on the material of the anode, thickness of the anode is typically in a range of 10 nm to 1 μm, and preferably in a range of 10 to 200 nm.

The cathode is preferably formed of a material with smaller work function in order to inject electrons into the electron injecting layer, the electron transporting layer or the emitting layer.

Although the material for the cathode is subject to no specific limitation, examples of the material are indium, aluminum, magnesium, alloy of magnesium and indium, alloy of magnesium and aluminum, alloy of aluminum and lithium, alloy of aluminum, scandium and lithium, and alloy of magnesium and silver.

Like the anode, the cathode may be made by forming a thin film from the above materials through a method such as vapor deposition or sputtering. In addition, the light may be emitted through the cathode.

Emitting Layer

The emitting layer of the organic EL device has functions as follows:

(1) injecting function: a function for accepting, when an electrical field is applied, the holes injected by the anode or the hole injecting layer, and the electrons injected by the cathode or the electron injecting layer;

(2) transporting function: a function for transporting injected electric charges (the electrons and the holes) by the force of the electrical field; and

(3) emitting function: a function for providing a condition for recombination of the electrons and the holes to emit light.

Injectability of the holes may differ from that of the electrons and transporting capabilities of the hole and the electrons (represented by mobilities of the holes and the electrons) may differ from each other.

As a method of forming the emitting layer, known methods such as vapor deposition, spin coating and an LB method may be employed.

The emitting layer is preferably a molecular deposit film.

The molecular deposit film means a thin film formed by depositing a material compound in gas phase or a film formed by solidifying a material compound in a solution state or in liquid phase. The molecular deposit film is typically distinguished from a thin film formed by the LB method (molecular accumulation film) by differences in aggregation structures and higher order structures and by functional differences arising therefrom.

The emitting layer can be formed from a thin film by spin coating or the like, the thin film being formed from a solution prepared by dissolving a binder (e.g. a resin) and a material compound in a solvent.

The thickness of the emitting layer is preferably in a range of 5 to 50 nm, more preferably in a range of 7 to 50 nm and most preferably in a range of 10 to 50 nm. The thickness below 5 nm may cause difficulty in forming the emitting layer and in controlling chromaticity, while the thickness above 50 nm may increase driving voltage.

The emitting layer of the organic EL device according to the exemplary embodiment preferably contains an organic compound represented by the formula (1) or (2) and a phosphorescent material.

As described above, in the formula (1) or (2) according to the exemplary embodiment, the Arᵢ is preferably one of a benzo[c]phenanthrene ring which may have the substituent and a benzo[g]chrysene ring which may have the substituent.

As described above, in the formula (1) or (2) according to the exemplary embodiment, the An is preferably one of a 5-benzo[c]phenanthrenyl group, a 6-benzo[c]phenanthrenyl group and a 10-benzo[g]chrysenyl group.

Regarding the naphthalene ring in the formula (1) and the dibenzofuran ring, benzo[c]phenanthrene ring and benzo[g]chrysene ring in the formula (2), the bonding positions are limited as above because when the rings are mutually bonded at their most easily oxidizable positions, it is possible to prevent oxidation caused by the holes, resulting in maintaining molecular stability to prolong the lifetime of the device.

Further, the organic compound represented by the formula (1) or (2) is formed mainly by a polycyclic fused ring containing no nitrogen atom in the same manner as a short-life phosphorescent host such as CBP, and thus molecular stability is enhanced to prolong the lifetime of the device.

The emitting layer of the organic EL device according to the exemplary embodiment contains the phosphorescent material in addition to the organic compound represented by the formula (1) or (2). In other words, the organic EL device is a phosphorescent device. Description will be made on a difference in emission mechanism between a fluorescent device and a phosphorescent device and the intended effect of the host material resulting from the emission mechanism.

In many of currently practical fluorescent devices, electrons and holes are transported by the host material in the emitting layer and recombination of the carriers is caused on the host to generate excitons. Applying the organic compound represented by the formula (1) or (2) to such a fluorescent device leads to an increase in driving voltage because a large energy gap is provided as compared with applying other possible fluorescent materials such as an anthracene derivative. In addition, since the hole-transporting capability of the organic compound represented by the formula (1) or (2) is poor, carrier balance is considerably disturbed. In view of the above, an anthracene derivative, which exhibits hole-injecting capability and hole-transporting capability, is the most suitable as the host material of a fluorescent device.

Regarding phosphorescent devices, a currently practical phosphorescent dopant containing a metal complex is excellent in hole-injecting capability and hole mobility. Further, the phosphorescent dopant emits light even at a high concentration as compared with a fluorescent dopant. In view of the above, it is possible to increase the content of the phosphorescent dopant. Even when the organic compound represented by the formula (1) or (2), which has a poor hole-transporting capability and a high electron-transporting capability, is used as the host material, carrier balance can be easily adjusted by appropriately adjusting the content of the phosphorescent dopant. In other words, when being used for a phosphorescent device, a material having a poor hole-transporting capability and a high electron-transporting capability provides a different effect as compared with the effect of the same material for a fluorescent device.

Since having great triplet energy, the organic compound represented by the formula (1) or (2) according to the exemplary embodiment is usable as a host for transferring energy to the phosphorescent dopant so that the phosphorescent dopant can emit light.

While an anthracene derivative, which is well-known as a fluorescent host, is not suitably applied as a host for a red-emiting phosphorescent dopant because of a significantly small triplet energy Eg(T) thereof, the organic compound represented by the formula (1) or (2) according to the exemplary embodiment, which exhibits great triplet energy, can be more effectively applied to the red-emitting phosphorescent dopant to emit light than an anthracene derivative.

However, while CBP, which is a conventionally known phosphorescent host, can serve as a host even for a phosphorescent dopant for emitting light of shorter wavelength than green, the organic compound represented by the formula (1) or (2) according to the exemplary embodiment is not suitable as a phosphorescent host for a green-emitting phosphorescent dopant because the triplet energy of the organic compound is not so large as that of CBP.

Conventionally, a host material widely usable for phosphorescent dopants that emit light of wide wavelengths ranging from green to red has been selected for phosphorescent dopants. Thus, CBP or the like having great triplet energy Eg(T) has been used as a host.

In this respect, the organic compound represented by the formula (1) or (2) according to the exemplary embodiment is not applicable as a host for such a wide-gap phosphorescent dopant as to be comparable to a blue-emitting or green-emitting phosphorescent dopant, bus is applicable as a host for a red-emitting phosphorescent dopant. Moreover, when the triplet energy Eg(T) is great as in CBP, a difference in energy between the host and the red-emitting phosphorescent dopant is so large that the energy is not efficiently transferred intermolecularly. However, since the organic compound represented by the formula (1) or (2) according to the exemplary embodiment has an excited energy value suitable for a red-emitting phosphorescent dopant, energy can be efficiently transferred from the excitons of the host to the phosphorescent dopant, thereby providing a phosphorescent-emitting layer exhibiting considerably high efficiency. Even when the phosphorescent dopant is directly excited, the organic compound represented by the formula (1) or (2) according to the exemplary embodiment, which has sufficiently greater triplet energy than that of the phosphorescent dopant, can efficiently trap the energy within the emitting layer.

Triplet energy Eg(T) of a material for forming an organic EL device may be exemplarily defined based on the phosphorescence spectrum. In the exemplary embodiment, the triplet energy Eg(T) may be defined as follows.

The organic copound is dissolved in an EPA solvent (diethylether: isopentane: ethanol=5:5:2 in volume ratio) with a concentration of 10 μmol/L, thereby forming a sample for phosphorescence measurement.

Then, the sample for phosphorescence measurement is put into a quartz cell, cooled to 77K and irradiated with exciting light, so that a wavelength of phosphorescence radiated therefrom is measured.

A tangent line is drawn to be tangent to a rising section adjacent to the short-wavelength side of the obtained phosphorescence spectrum, and a wavelength value at an intersection of the tangent line and a base line is converted into energy value. Then, the converted energy value is defined as the triplet energy Eg(T). For the measurement, for instance, a commercially-available FLUOROLOG II (manufactured by SPEX Corporation) may be used.

Alternatively, the triplet energy Eg(T) may be obtained by the quantum chemical calculation as follows.

The quantum chemical calculation may be performed using a quantum chemical calculation program, Gaussian03 (manufactured by Gaussian Inc. (US)). Gaussian03 is a program developed by J. A. Pople et al. (a winner of the 1998 Nobel Prize in Chemistry), and is applicable to a variety of molecular systems for predicting molecular properties such as energy, structure and normal frequencies through various quantum chemical calculation methods. For calculation, the density functional theory (DFT) is used. For an arrangement optimized using B3LYP as a functional and 6-31G* as a base function, a value of the triplet energy can be calculated through the time dependent density functional theory (TD-DFT).

In the exemplary embodiment, a tangent line is drawn to be tangent to a rising section adjacent to the short-wavelength side of the phosphorescence spectrum, and a wavelength value at an intersection of the tangent line and a base line is converted into energy value. Then, the converted energy value is defined as the triplet energy gap Eg(T). However, no phosphorescence spectrum may be observed in specific kinds of organic compounds. For such organic compounds, a triplet energy Eg(T) obtained by the above quantum chemical calculation is used.

As described above, the triplet energy Eg(T) of the organic compound represented by the formula (1) or (2) according to the exemplary embodiment is preferably in a range of 2.2 eV to 2.7 eV.

When the triplet energy is 2.2 eV or more, energy can be transferred to a phosphorescent material that emits light in a range of 600 to 720nm. When the triplet energy is 2.7 eV or more, it is possible to prevent an extremely large difference in triplet energy between the host material and the red dopant in the emitting layer, so that driving voltage is not increased to prevent emission lifetime from being shortened.

The triplet energy of the organic compound represented by the formula (1) or (2) according to the exemplary embodiment is preferably in a range of 2.2 eV to 2.5 eV, more preferably in a range of 2.2 eV to 2.3 eV.

When each group represented by Ar₁ in the formula (1) or (2) has a specific structure as described above, it is possible to optimize the triple energy level and to provide a long-life device.

The following are examples of the organic compound represented by the formula (1) or (2).

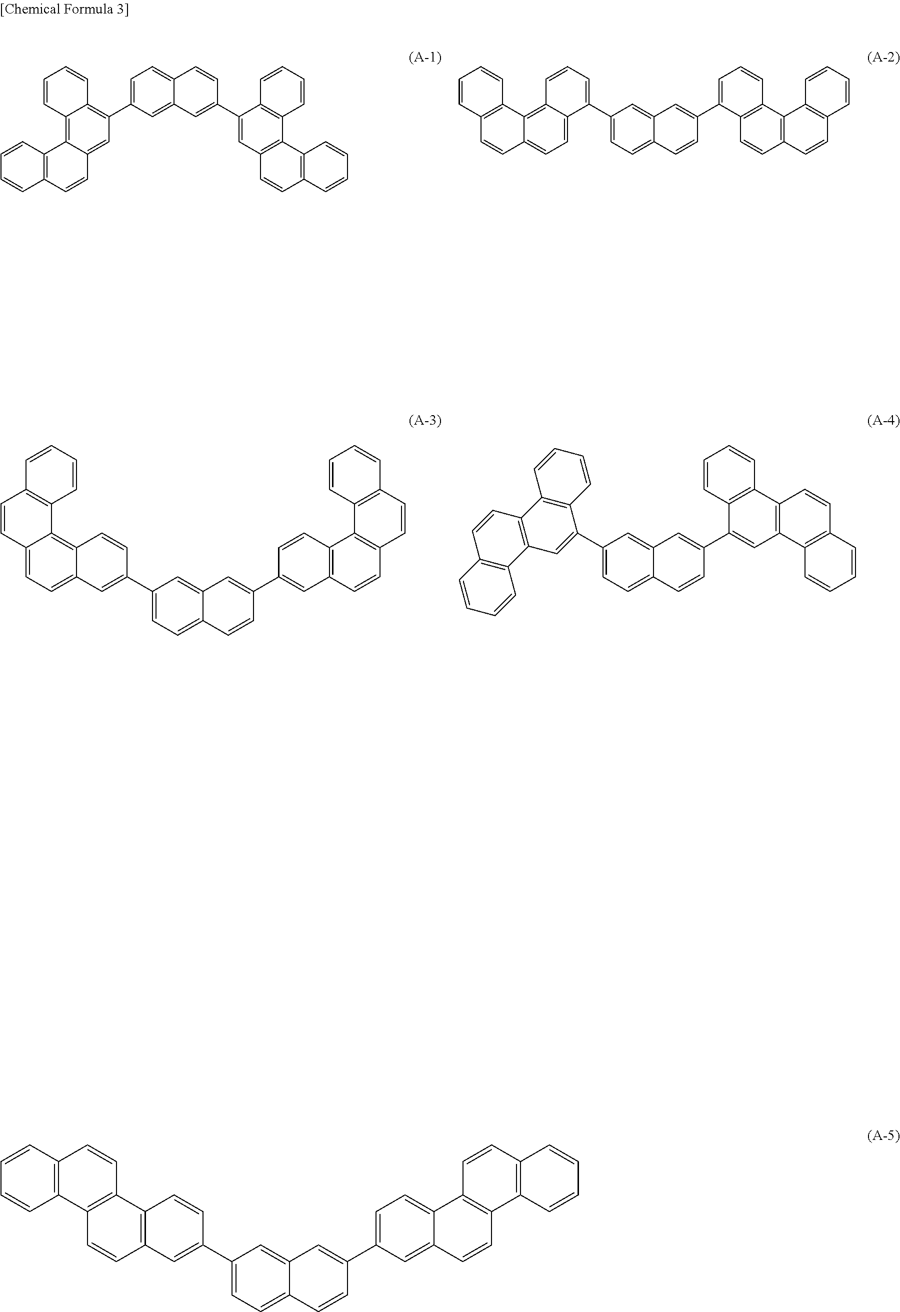

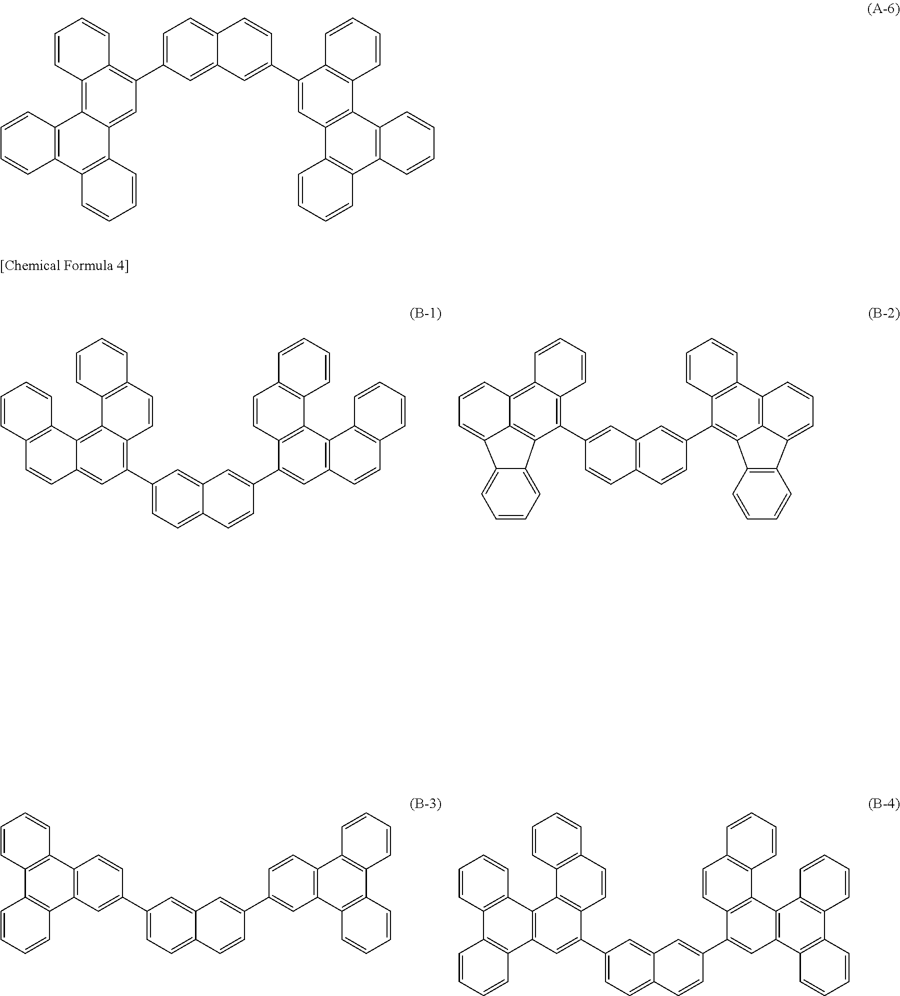

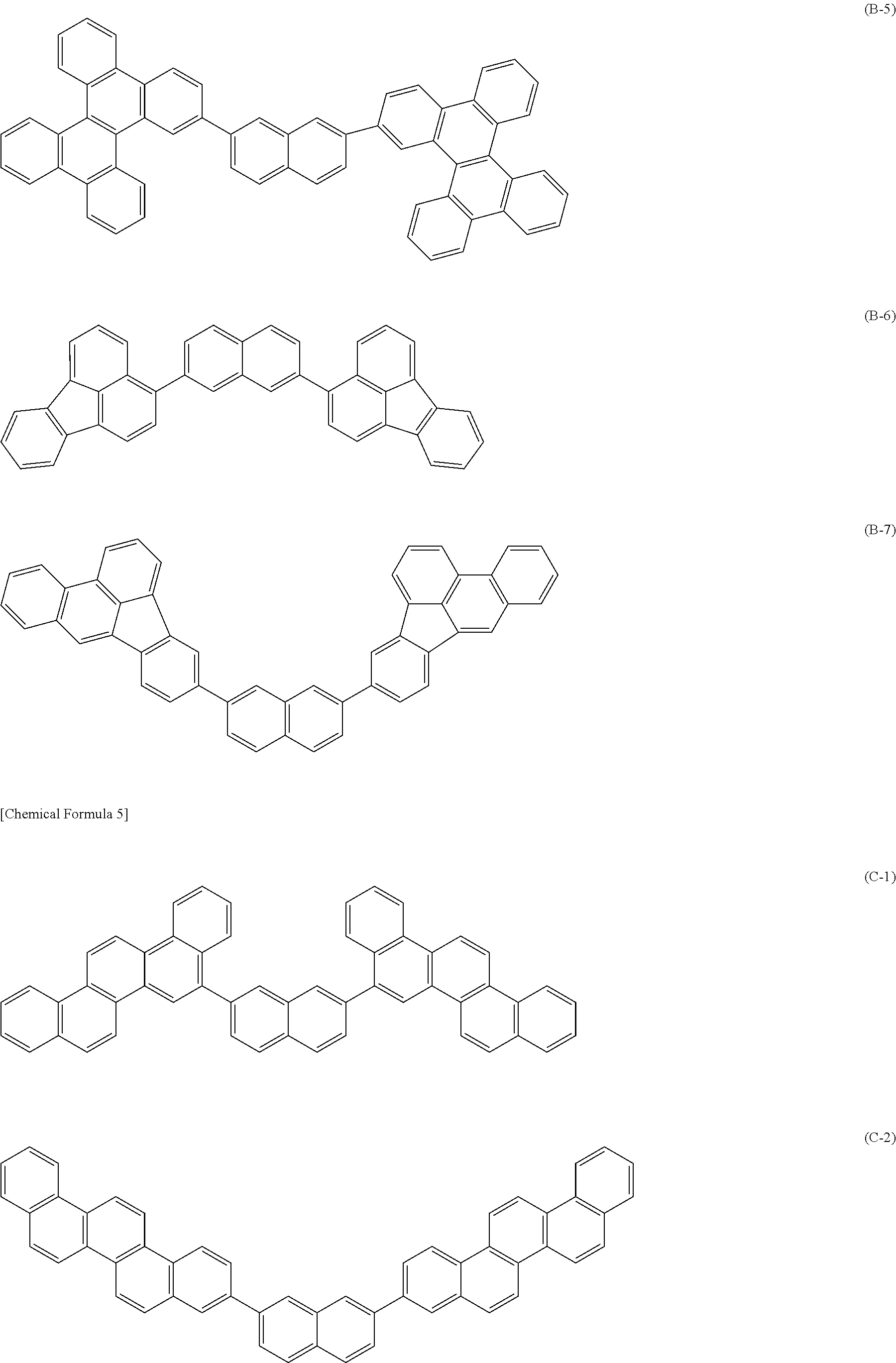

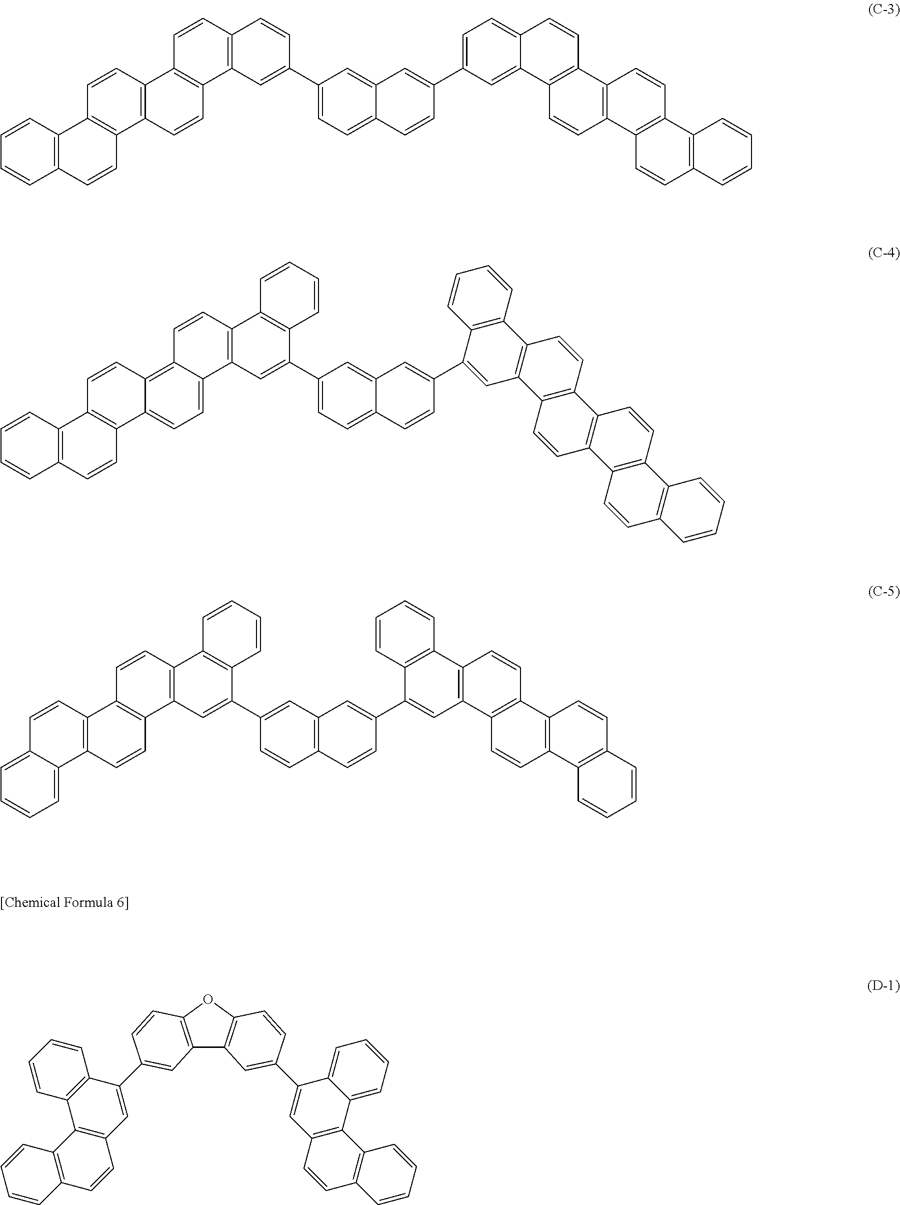

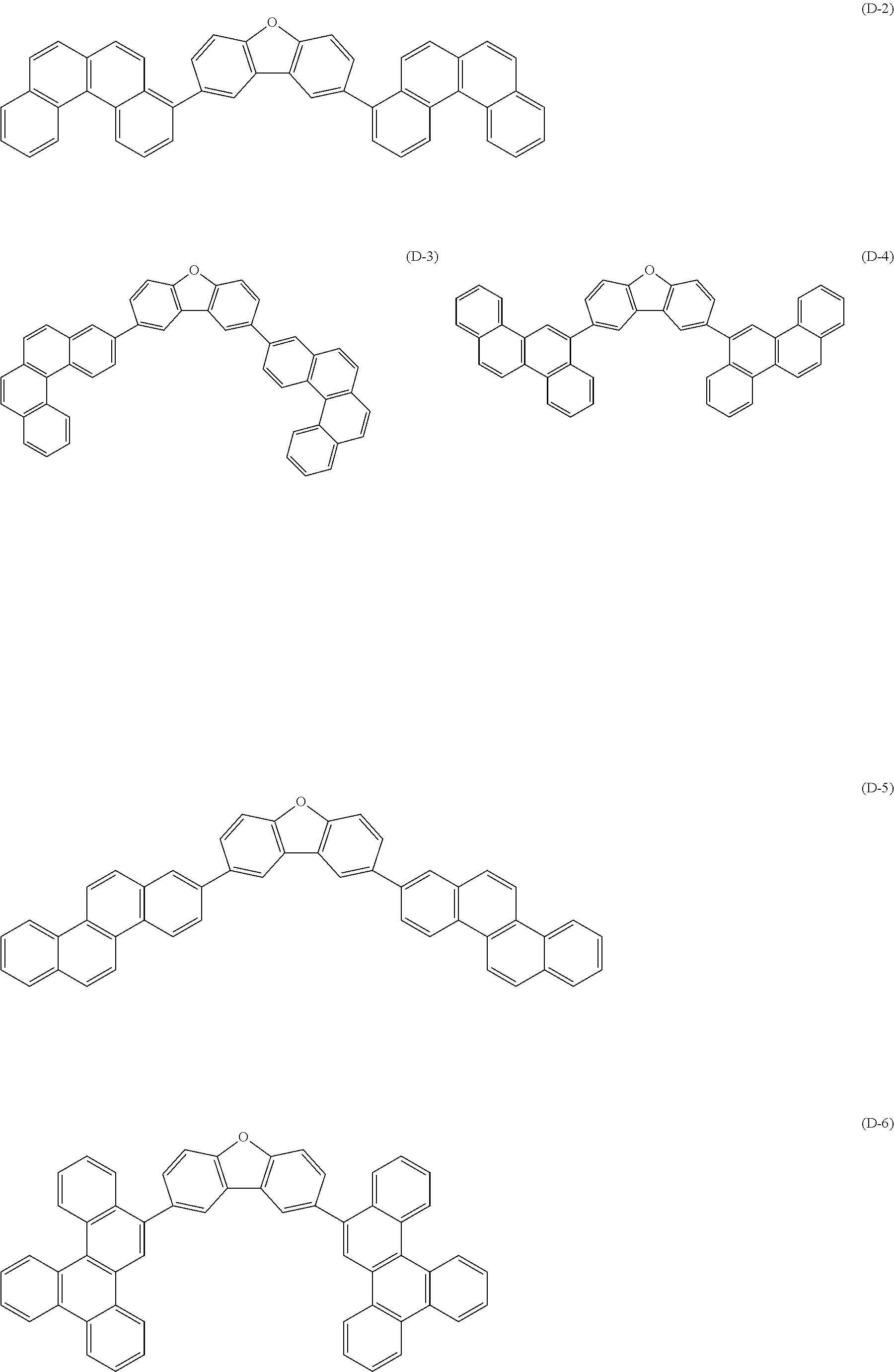

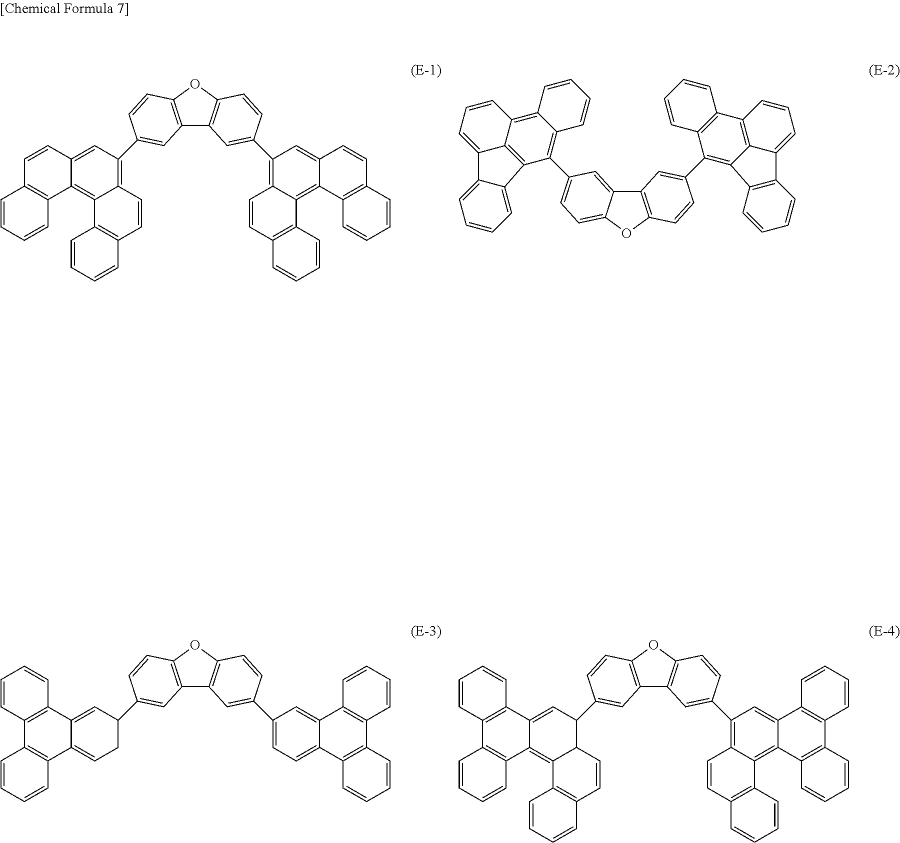

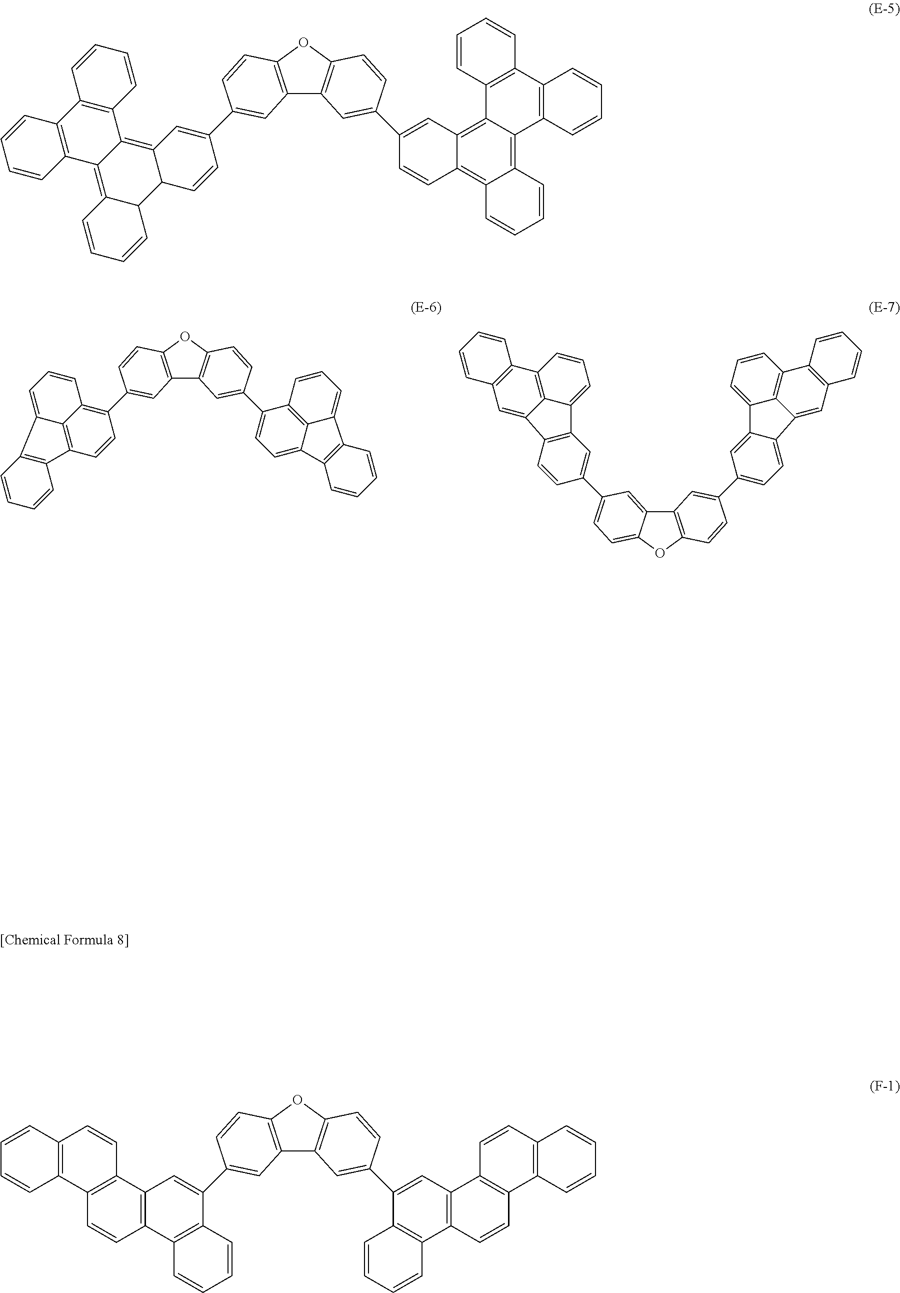

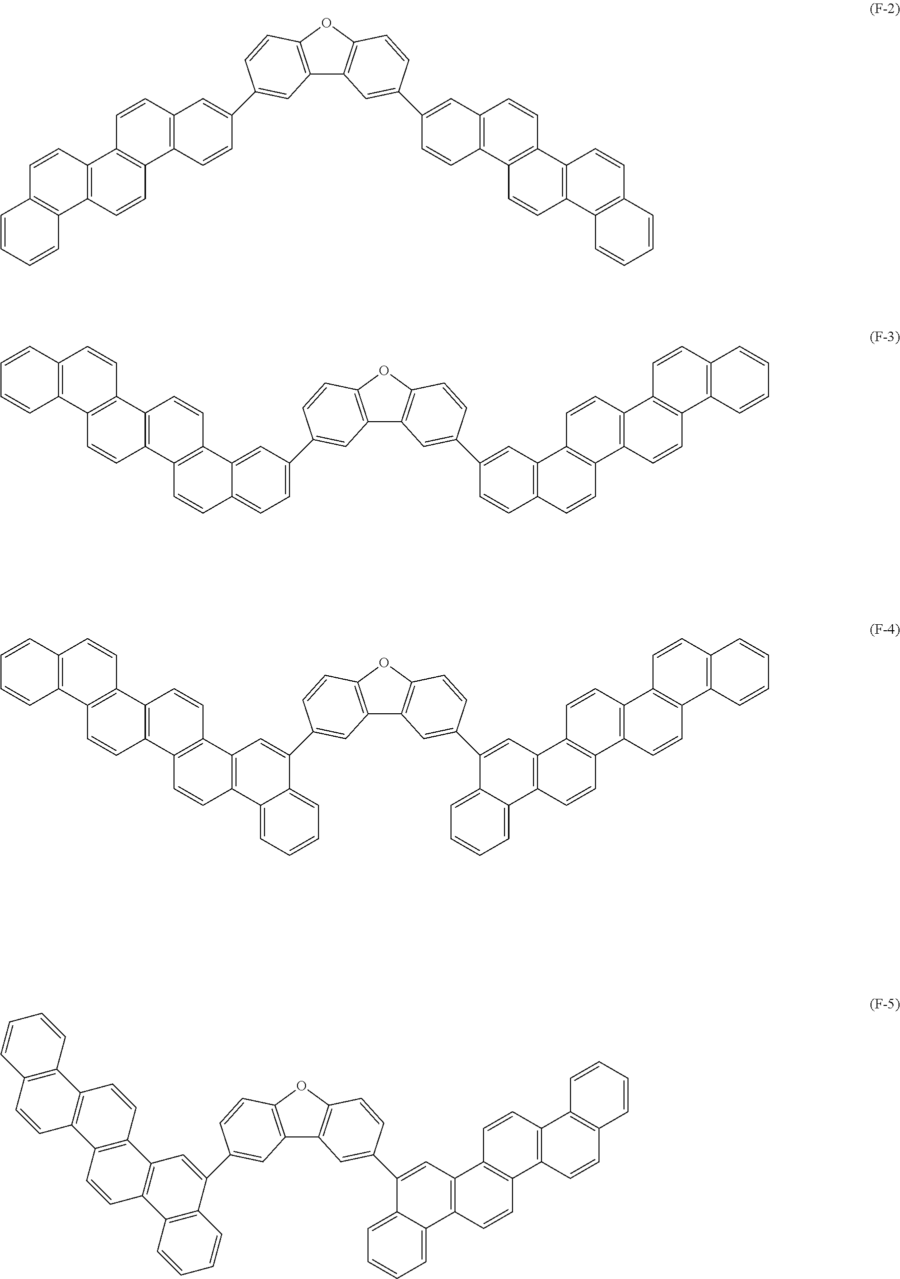

Phosphorescent Material

The phosphorescent material used in the exemplary embodiment, which generates phosphorescent emission, preferably contains a metal complex. The metal complex is preferably a metal complex having a metal atom selected from Ir, Pt, Os, Au, Re and Ru, and a ligand. Particularly, the ligand and the metal atom preferably form an ortho-metal bond.

The phosphorescent material is preferably a compound containing a metal selected from iridium (Ir), osmium (Os) and platinum (Pt) because such a compound, which exhibits high phosphorescence quantum yield, can further enhance external quantum efficiency of the emitting device. The phosphorescent material is more preferably a metal complex such as an iridium complex, osmium complex or platinum complex, among which an iridium complex and platinum complex are more preferable and ortho metalation of an iridium complex is the most preferable. The organic metal complex formed of the ligand selected from the group consisting of phenyl quinoline, phenyl isoquinoline, phenyl pyridine, phenyl pyrimidine, phenyl pyrazine and phenyl imidazoles is preferable in terms of luminous efficiency and the like.

Examples of the metal complex are shown below, but the metal complex is not limited thereto.

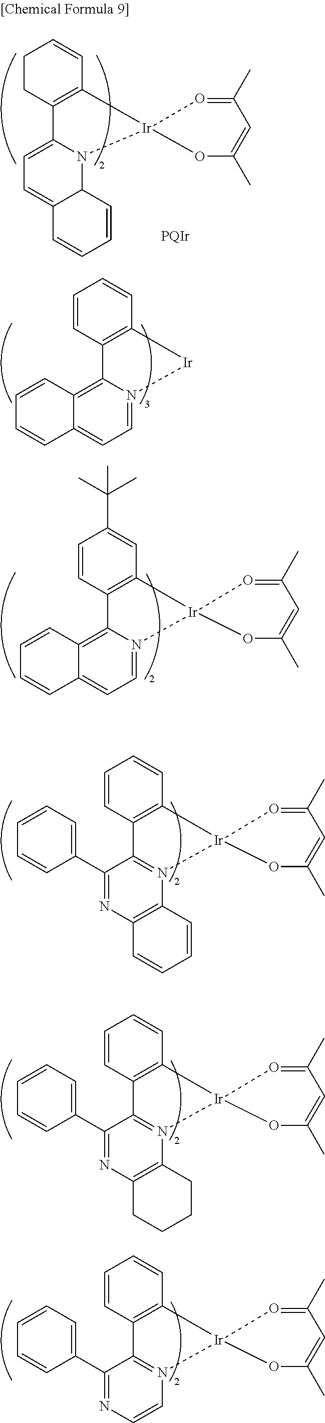

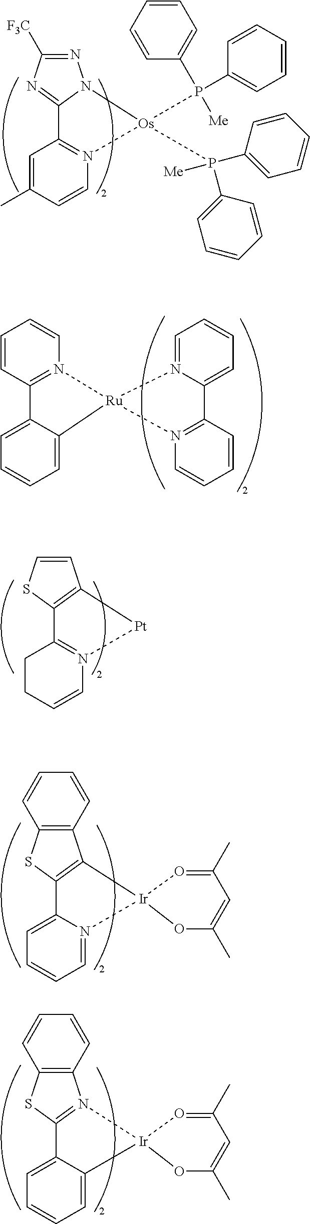

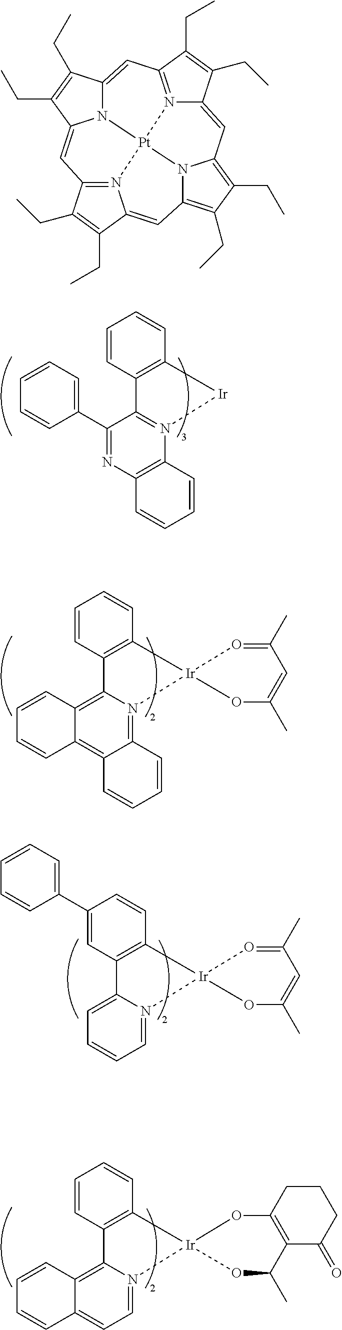

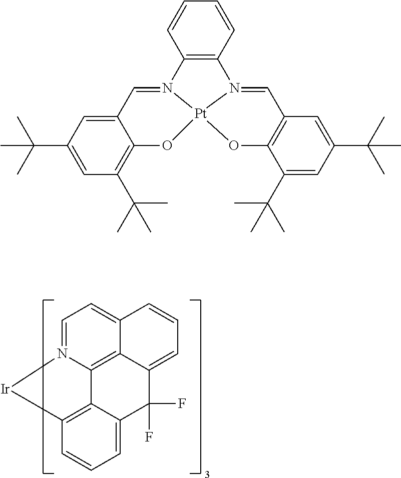

In the exemplary embodiment, at least one of the phosphorescent material contained in the emitting layer more preferably emits light having a maximum emission wavelength of 600 nm to 720 nm.

By doping the phosphorescent material (phosphorescent dopant) having such an emission wavelength to the specific host usable for the exemplary embodiment so as to form the emitting layer, the organic EL device can exhibit high efficiency.

Electron Transporting Layer or Electron Injecting Layer

The organic EL device according to the exemplary embodiment may include an electron transporting layer or an electron injecting layer provided between the emitting layer and the cathode.

The electron injecting layer or the electron transporting layer, which aids injection of the electrons into the emitting layer, has a high electron mobility. The electron injecting layer is provided for adjusting energy level, by which, for instance, sudden changes in the energy level can be reduced.

A preferable example of an electron transporting material for forming the electron transporting layer or the electron injecting layer is an aromatic heterocyclic compound having in the molecule at least one heteroatom. Particularly, a nitrogen-containing cyclic derivative is preferable. The nitrogen-containing cyclic derivative is preferably a heterocyclic compound having a nitrogen-containing six-membered or five membered ring skeleton.

A preferable specific compound is a nitrogen-containing heterocyclic derivative represented by the following formula (3).

[Chemical Formula 10]

HAr—L¹—Ar¹—Ar² (3)

In the formula (3), HAr represents a substituted or unsubstituted nitrogen-containing heterocycle having 3 to 40 carbon atoms; L¹ represents a single bond, substituted or unsubstituted arylene group having 6 to 40 carbon atoms or substituted or unsubstituted heteroarylene group having 3 to 40 carbon atoms; Ar^{l} represents a substituted or unsubstituted divalent aromatic hydrocarbon group having 6 to 40 carbon atoms; and Ar^{e} represents a substituted or unsubstituted aryl group having 6 to 40 carbon atoms or substituted or unsubstituted heteroaryl group having 3 to 40 carbon atoms.

HAr is exemplarily selected from the following group.

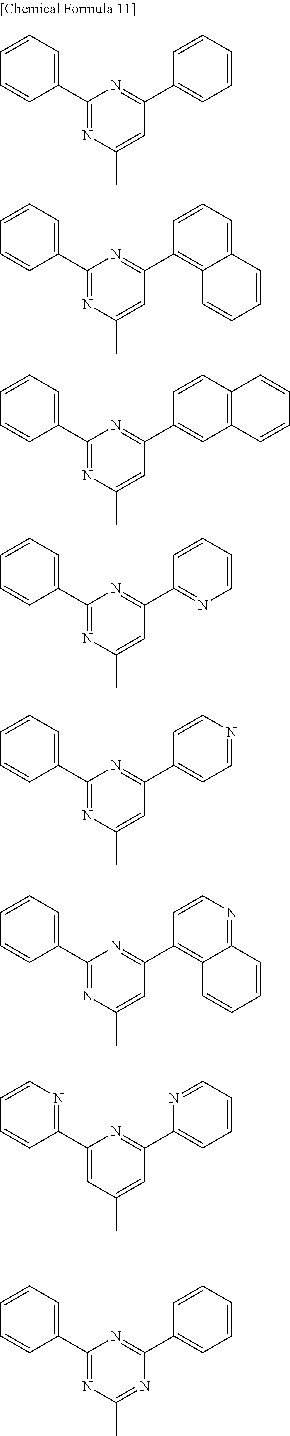

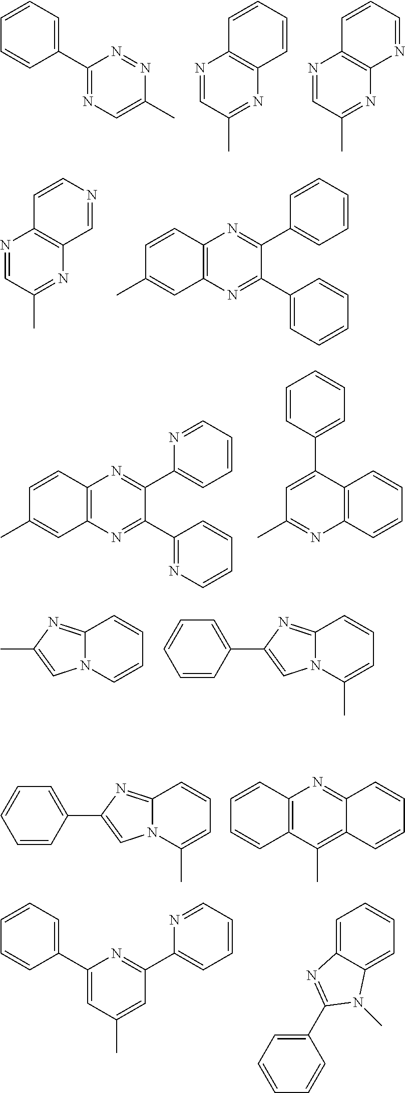

L¹ is exemplarily selected from the following group.

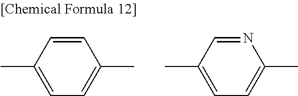

Ar² is exemplarily selected from the following group.

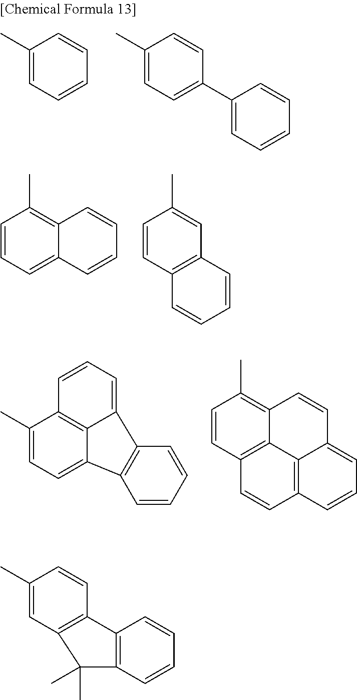

Ar¹ is exemplarily selected from the following arylanthranil groups.

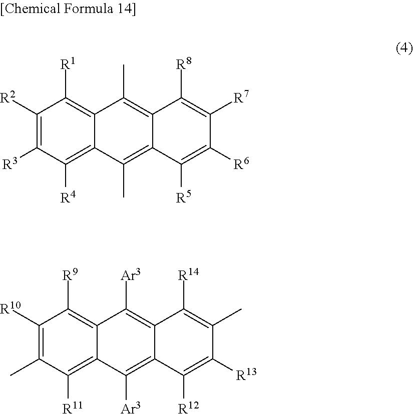

In the formula (4), R¹ to R¹⁴ each independently represent a hydrogen atom, a halogen atom, an alkyl group having 1 to 20 carbon atoms, an alkoxy group having 1 to 20 carbon atoms, an aryloxy group having 6 to 40 carbon atoms, a substituted or unsubstituted aryl group having 6 to 40 carbon atoms, or a heteroaryl group having 3 to 40 carbon atoms. Ar^{a} represents a substituted or unsubstituted aryl group having 6 to 40 carbon atoms, or a heteroaryl group having 3 to 40 carbon atoms.

Although thickness of the electron injecting layer or the electron transporting layer is not specifically limited, the thickness is preferably 1 to 100 nm.

The electron injecting layer preferably contains an inorganic compound such as an insulator or a semiconductor in addition to the nitrogen-containing cyclic derivative. Such an insulator or a semiconductor, when contained in the electron injecting layer, can effectively prevent a current leak, thereby enhancing electron injecting capability of the electron injecting layer.

As the insulator, it is preferable to use at least one metal compound selected from the group consisting of an alkali metal chalcogenide, an alkali earth metal chalcogenide, a halogenide of alkali metal and a halogenide of alkali earth metal. By forming the electron injecting layer from the alkali metal chalcogenide or the like, the electron injecting capability can be further enhanced. Specifically, preferable examples of the alkali metal chalcogenide are Li₂O, K₂O, Na₂S, Na₂Se and Na₂O. Preferable examples of the alkali earth metal chalcogenide are CaO, BaO, SrO, BeO, BaS and CaSe. Preferred examples of the halogenide of the alkali metal are LiF, NaF, KF, LiCl, KCl and NaCl. Preferred examples of the halogenide of the alkali earth metal are fluorides such as CaF₂, BaF₂, SrF₂, MgF₂ and BeF₂, and halogenides other than the fluoride.

Examples of the semiconductor include one of or a combination of two or more of an oxide, a nitride or an oxidized nitride containing at least one element selected from Ba, Ca, Sr, Yb, Al, Ga, In, Li, Na, Cd, Mg, Si, Ta, Sb and Zn. An inorganic compound for forming the electron injecting layer is preferably a microcrystalline or amorphous semiconductor film. When the electron injecting layer is formed of such semiconductor film, more uniform thin film can be formed, thereby reducing pixel defects such as a dark spot. Examples of such an inorganic compound are the alkali metal chalcogenide, alkali earth metal chalcogenide, halogenide of the alkali metal and halogenide of the alkali earth metal.

When the electron injecting layer contains such an insulator or semiconductor, the thickness thereof is preferably in a range of approximately 0.1 nm to 15 nm. The electron injecting layer in the exemplary embodiment may preferably contain a reduction-causing dopant described below.

In the organic EL device according to the exemplary embodiment of the invention, a reduction-causing dopant may be preferably contained in an interfacial region between the cathode and the organic thin-film layer.

With this arrangement, the organic EL device can emit light with enhanced luminance intensity and have a longer lifetime.

The reduction-causing dopant may be at least one compound selected from an alkali metal, an alkali metal complex, an alkali metal compound, an alkali earth metal, an alkali earth metal complex, an alkali earth metal complex, a rare-earth metal, a rare-earth metal complex, a rare-earth metal compound and the like.

Examples of the alkali metal are Na (work function: 2.36 eV), K (work function: 2.28 eV), Rb (work function: 2.16 eV) and Cs (work function: 1.95 eV). The alkali metal particularly preferably has a work function of 2.9 eV or less. Among the above, the alkali metal is preferably K, Rb or Cs, more preferably Rb or Cs, the most preferably Cs.

Examples of the alkali earth metal are Ca (work function: 2.9 eV), Sr (work function: 2.0 to 2.5 eV) and Ba (work function: 2.52 eV). The alkali earth metal particularly preferably has a work function of 2.9 eV or less.

Examples of the rare-earth metal are Sc, Y, Ce, Tb, Yb and the like. The rare-earth metal particularly preferably has a work function of 2.9 eV or less.

Since the above preferred metals have particularly high reducibility, addition of a relatively small amount of the metals to an electron injecting zone can enhance luminance intensity and lifetime of the organic EL device.

Examples of the alkali metal compound are an alkali oxide such as Li₂O, Cs₂O or K₂O and an alkali halogenide such as LiF, NaF, CsF or KF, among which LiF, Li₂O and NaF are preferable.

Examples of the alkali earth metal compound are BaO, SrO, CaO, and a mixture thereof such as BaₓSr₁₋ₓO (0<x<1) or BaₓCa₁₋ₓO (0<x<1), among which BaO, SrO and CaO are preferable.

Examples of the rare-earth metal compound are YbF₃, ScF₃, ScO₃, Y₂O₃, Ce₂O₃, GdF₃ and TbF₃, among which YbF₃, ScF₃ and TbF₃ are preferable.

The alkali metal complex, alkali earth metal complex and rare earth metal complex are not specifically limited as long as they contain at least one metal ion of an alkali metal ion, an alkali earth metal ion and a rare earth metal ion. The ligand is preferably quinolynol, benzoquinolynol, acridinol, phenanthridinol, hydroxyphenyloxazole, hydroxyphenylthiazole, hydroxydiaryloxadiazole, hydroxydiarylthiadiazole, hydroxyphenylpyridine, hydroxyphenylbenzoimidazole, hydroxybenzotriazole, hydroxyfluboran, bipyridyl, phenanthroline, phthalocyanin, porphyrin, cyclopentadiene, β-diketones, azomethines, and derivatives thereof. However, the ligand is not limited thereto.

The reduction-causing dopant is added to preferably form a layer or an island pattern in the interfacial region. The layer of the reduction-causing dopant or the island pattern of the reduction-causing dopant is preferably formed by depositing the reduction-causing dopant by resistance heating deposition while an emitting material for forming the interfacial region or an organic substance as an electron-injecting material are simultaneously deposited, so that the reduction-causing dopant is dispersed in the organic substance. Dispersion concentration at which the reduction-causing dopant is dispersed in the organic substance is a mole ratio (organic substance to reduction-causing dopant) of 100:1 to 1:100, preferably 5:1 to 1:5.

When the reduction-causing dopant forms the layer, the emitting material or the electron injecting material for forming the organic layer of the interfacial region is initially layered, and the reduction-causing dopant is subsequently deposited singularly thereon by resistance heating deposition to form a preferably 0.1 to 15 nm-thick layer.

When the reduction-causing dopant forms an island pattern, the emitting material or the electron injecting material for forming the organic layer of the interfacial region is initially formed in the island shape, and the reduction-causing dopant is subsequently deposited singularly thereon by resistance heating deposition to form a preferably 0.05 to 1 nm-thick island shape.

A ratio of the main component (an organic substance forming the interfacial region) to the reduction-causing dopant in the organic EL device according to the exemplary embodiment is preferably a mole ratio (main component to reduction-causing dopant) of 5:1 to 1:5, more preferably 2:1 to 1:2.

Hole Injecting Layer or Hole Transporting Layer

The organic EL device according to the exemplary embodiment may include a hole injecting layer or a hole transporting layer (including a hole injecting/transporting layer), which preferably contains an aromatic amine compound such as an aromatic amine derivative represented by the following formula (I).

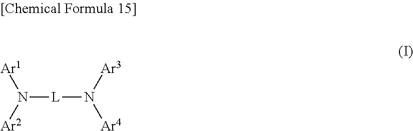

In the formula (I), L and Ar¹ to Ar⁴ each represent a substituted or unsubstituted aryl group having 6 to 50 carbon atoms for forming the aromatic ring (hereinafter abbreviated as ring carbon atoms) or a substituted or unsubstituted heteroaryl group having 5 to 50 ring atoms.

Aromatic amine represented by the following formula (II) can also be preferably used for forming the hole injecting layer or the hole transporting layer.

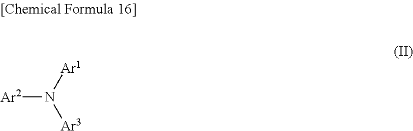

In the above formula (II), Ar¹ to Ar³ each represent the same as Ar¹ to Ar⁴ of the formula (I). Examples of the compound represented by the formula (II) are shown below. However, the compound is not limited thereto.

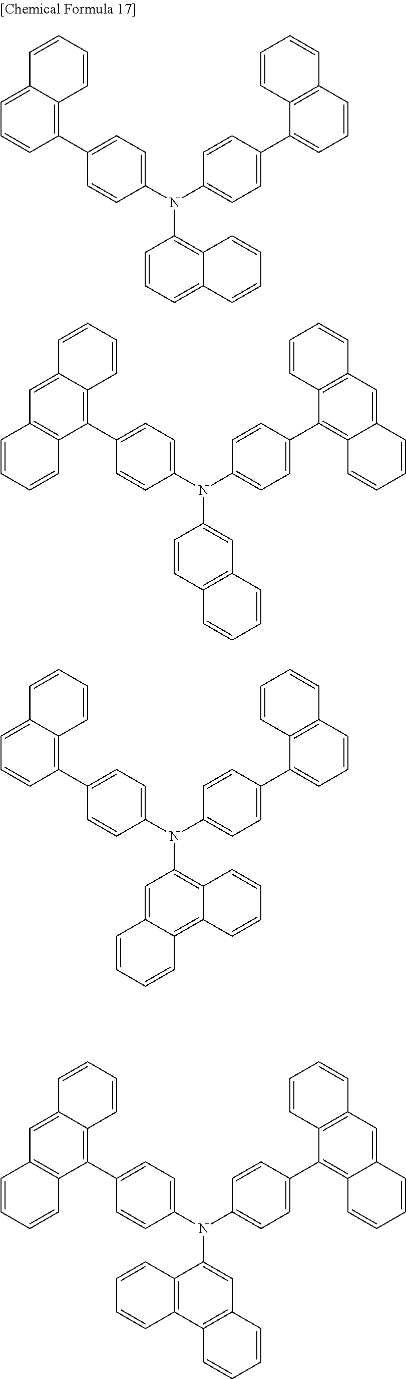

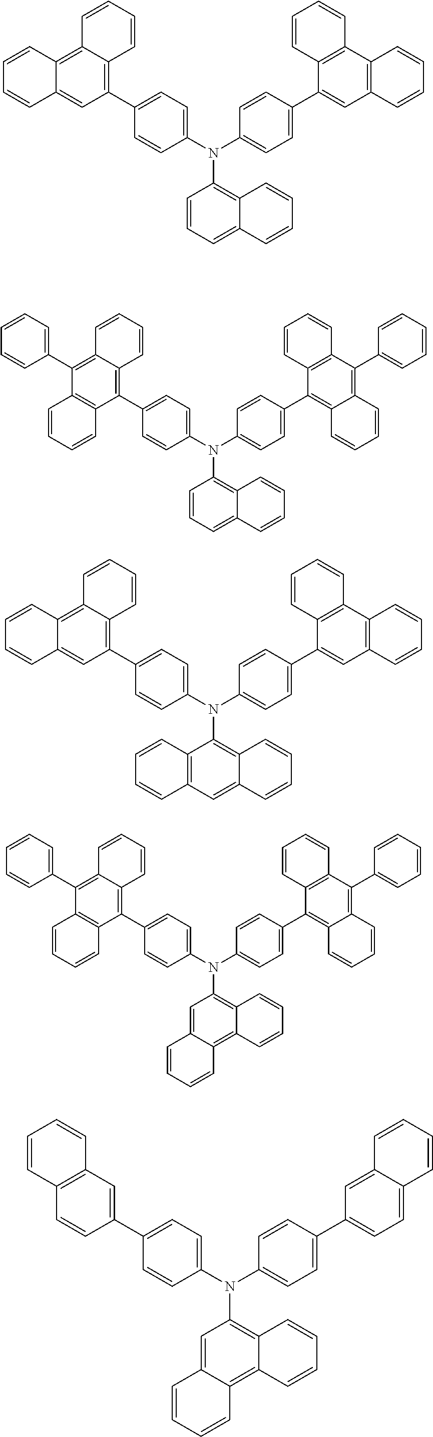

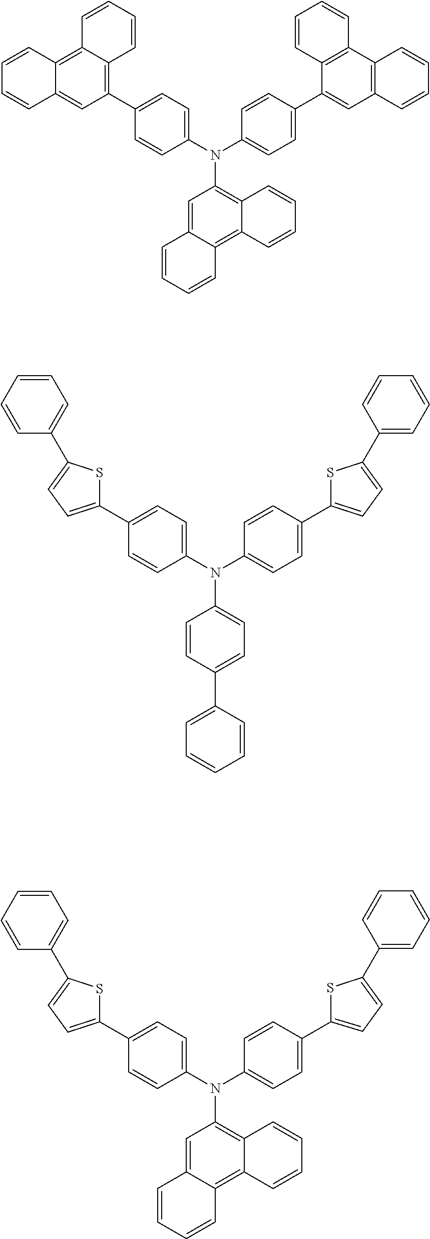

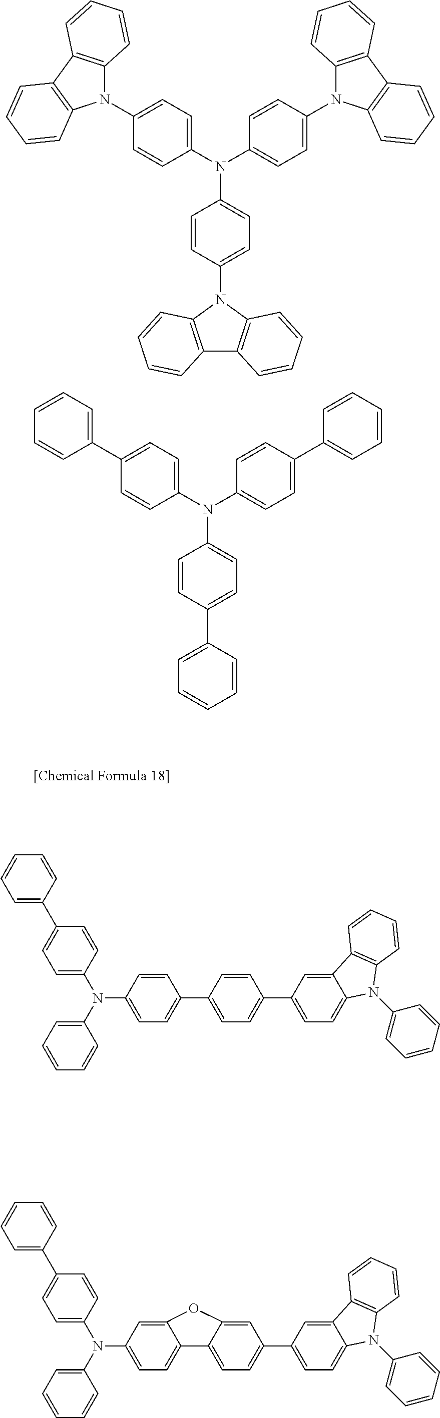

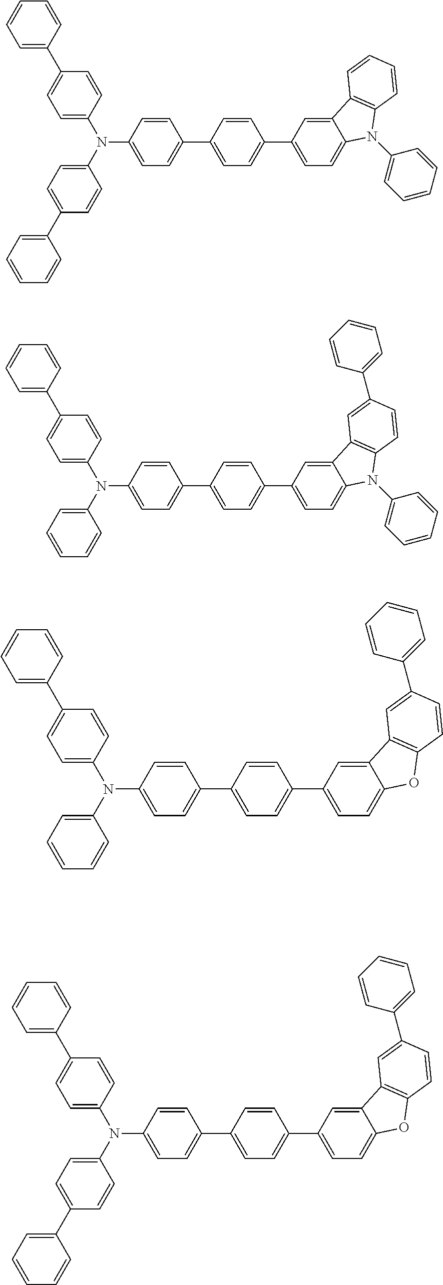

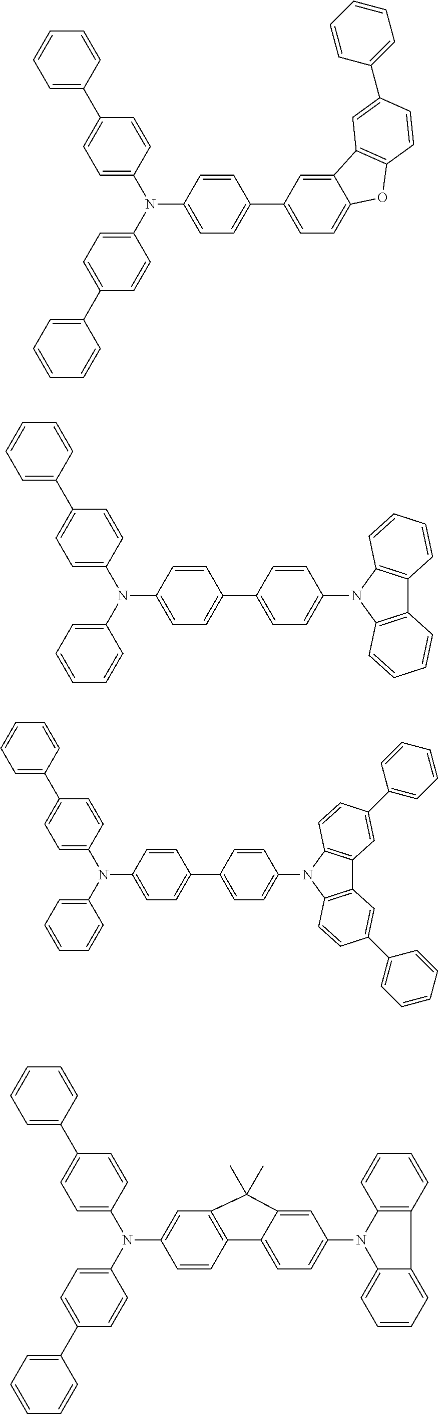

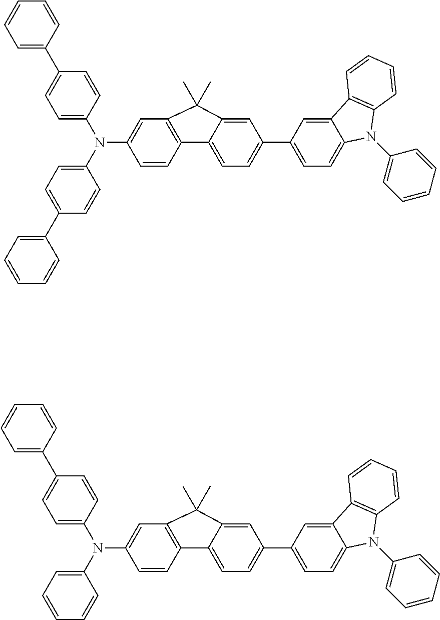

It should be noted that the invention is not limited to the above description but may include any modification as long as such modification stays within a scope and a spirit of the invention.

For instance, the following is a preferable example of such modification made to the invention.

According to the invention, the emitting layer may also preferably contain an assistance substance for assisting injection of charges.

When the emitting layer is formed of a host that exhibits a wide energy gap, a difference in ionization potential (Ip) between the host and the hole injecting/transporting layer etc. becomes so large that injection of the holes into the emitting layer becomes difficult, which may cause a rise in a driving voltage required for providing sufficient luminance.

In the above instance, introducing a hole-injectable or hole-transportable assistance substance for assisting injection of charges in the emitting layer can contribute to facilitation of the injection of the holes into the emitting layer and to reduction of the driving voltage.

As the assistance substance for assisting the injection of charges, for instance, a general hole injecting/transporting material or the like is usable.

Examples of the assistance material for assisting the injection of charges are triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, stilbene derivatives, silazane derivatives, polysilane-base copolymers, aniline-base copolymers and conductive polymer oligomers (in particular, thiophene oligomer).

The hole injecting material is exemplified by the above. The hole injecting material is preferably a porphyrin compound, aromatic tertiary amine compound and styryl amine compound, particularly preferably aromatic tertiary amine compound.

In addition, 4,4′-bi s(N-(1 -naphthyl)-N-phenylamino)biphenyl (hereinafter abbreviated as NPD) having in the molecule two fused aromatic rings, 4,4′,4″-tris(N-(3-methylphenyl)-N-phenylamino) triphenylamine (hereinafter abbreviated as MTDATA) in which three triphenylamine units are bonded in a starbust form, and the like may also be used.

Moreover, a hexaazatriphenylene derivative and the like can also be suitably used as the hole injecting material.

Alternatively, inorganic compounds such as p-type Si and p-type SiC can also be used as the hole injecting material.

In the above description of the exemplary embodiment, the compound represented by the formula (1) or (2) is exemplarily used in the emitting layer along with the phosphorescent material. However, the compound represented by the formula (1) or (2) may be used in any other organic thin-film layer.

Specifically, a layer containing the compound represented by the formula (1) or (2) may be formed between the emitting layer and the electron injecting/transporting layer to function as an exciton blocking layer adapted to prevent leakage of excitons generated in the emitting layer into the electron injecting/transporting layer.

The following is an exemplary device arrangement in which the layer containing the compound represented by the formula (1) or (2) is used as the exciton blocking layer. anode/hole injecting·transporting layer/emitting layer/a layer containing the compound represented by the formula (1) or (2)/electron injecting·transporting layer/cathode.

The exciton blocking layer preferably has a thickness of 10 nm, more preferably 5 nm.

A method of forming each of the layers in the organic EL device according to the exemplary embodiment of the invention is not particularly limited. A conventionally-known methods such as vacuum deposition or spin coating may be employed for forming the layers. The organic thin-film layer containing the compound represented by the formula (1) or (2), which is used in the organic EL device according to the exemplary embodiment of the invention, may be formed by a conventional coating method such as vacuum deposition, molecular beam epitaxy (MBE method) and coating methods using a solution such as a dipping, spin coating, casting, bar coating, and roll coating.

Although the thickness of each organic layer of the organic EL device is not particularly limited, the thickness is generally preferably in a range of several nanometers to 1 μm because an excessively-thinned film likely entails defects such as a pin hole while an excessively-thickened film requires high voltage to be applied and deteriorates efficiency.

### Examples

Next, the invention will be described in further detail with reference to Examples and Comparatives. However, the invention is not limited by the description of Examples.

### Example 1

Manufacturing of Organic EL Device A glass substrate (size: 25 mm×75 mm×0.7mm thick) having an ITO transparent electrode (manufactured by Asahi Glass Co., Ltd) was ultrasonic-cleaned in isopropyl alcohol for five minutes, and then UV/ozone-cleaned for 30 minutes. After the glass substrate having the transparent electrode line was cleaned, the glass substrate was mounted on a substrate holder of a vacuum deposition apparatus so that a 50-nm thick film of the following compound HT1 was initially formed on a surface of the glass substrate where the transparent electrode line was provided so as to cover the transparent electrode.

The compound HT1 film serves as a hole injecting/transporting layer. Subsequently to the formation of the hole injecting/transporting layer, a 40-nm thick film of the compound (A-1) and a film of the following compound Ir(piq)₃ as a phosphorescent dopant (phosphorescent material) were co-evaporated on the hole injecting/transporting layer by resistance heating so that Ir(piq)₃ was contained therein with a content of 10 mass %. The co-evaporated film serves as an emitting layer (phosphorescent-emitting layer). An emission wavelength of the following compound Ir(piq)₃ is 629 nm. After the film of the emitting layer was formed, a 40-nm thick film of the following compound ET1 was formed. The film of the compound ET1 serves as an electron transporting layer. Then, a 0.5-nm thick film of LiF was formed as an electron-injecting electrode (cathode) at a film-forming speed of 0.1 nm/min. Metal (Al) was vapor-deposited on the LiF film to form an 80-nm thick metal cathode, thereby providing the organic EL device.

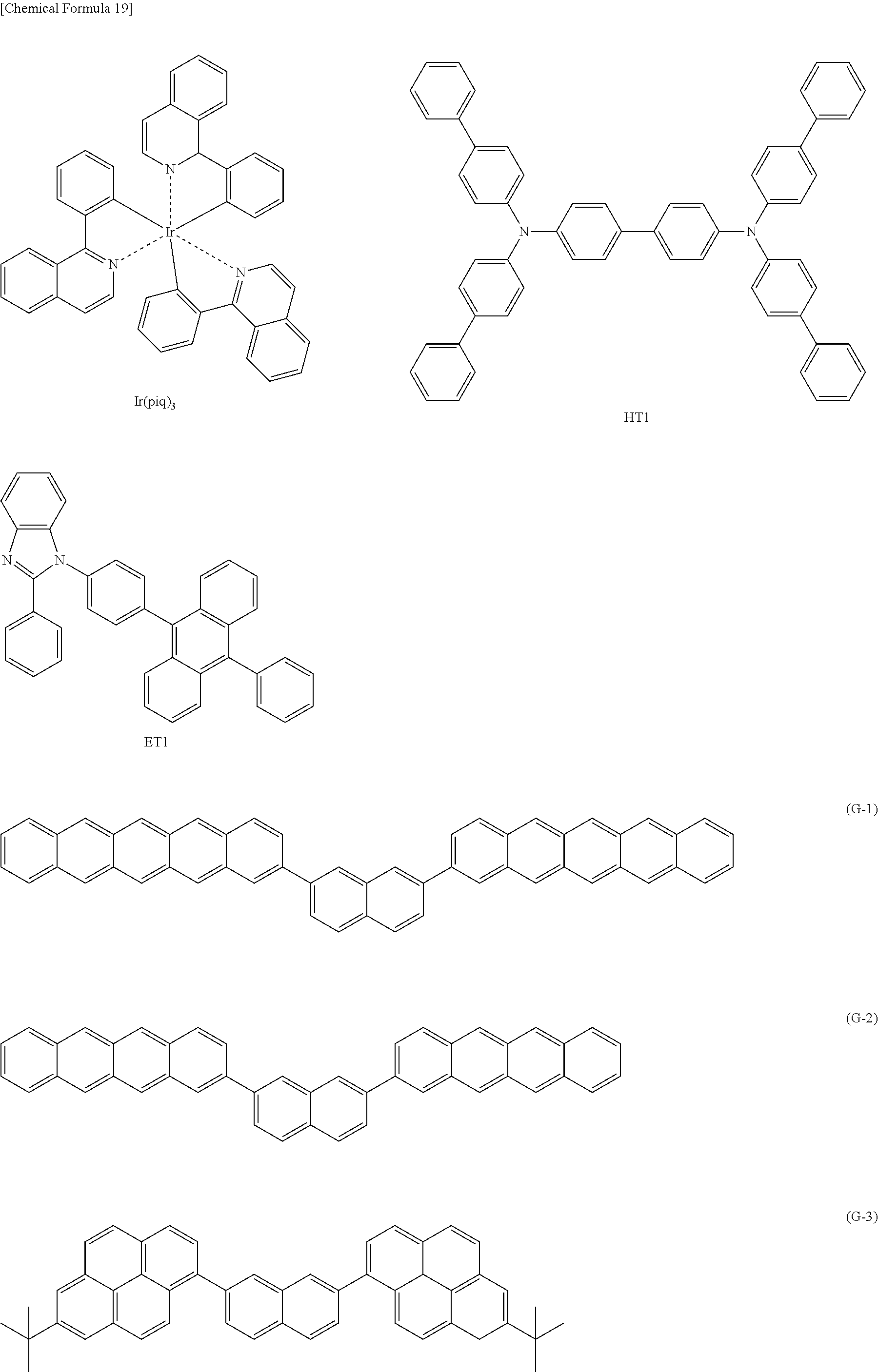

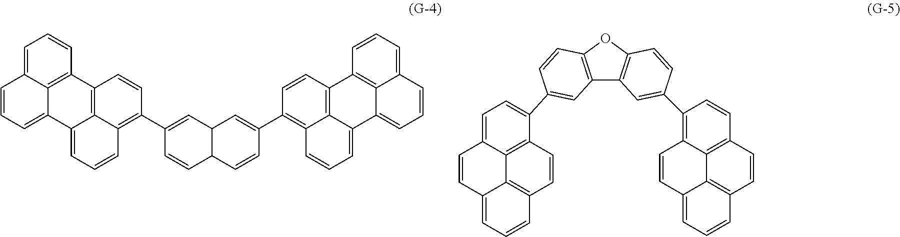

Examples 2 to 3 and Comparatives 1 to 5.

The respective organic EL devices according to Examples 2 to 3 and Comparatives 1 to 5 were formed by the same method as that of Example 1 except that compounds shown in Table 1 were used in place of the compound (A-1) used in Example 1.

Evaluation on Emitting Performance of Organic EL Device

The organic EL devices according to Examples 1 to 3 and Comparatives 1 to 5 each were driven by direct-current electricity to emit light, and then luminous efficiency and time elapsed until the initial luminance intensity of 10,000 cd/m² was reduced to the half (i.e., time until half-life) at a current density of 10 mA/cm² were measured for each organic EL device. The results of the evaluation are shown in Table 1.

A tangent line was drawn to be tangent to a rising section adjacent to the short-wavelength side of the phosphorescence spectrum as described above, and a wavelength value at an intersection of the tangent line and a base line was converted into energy value. Then, the converted energy value was defined as the triplet energy gap Eg(T) of each organic compound.

The measured value of Eg(T) of the phosphorescent dopant (Ir(piq)₃) used in Examples and Comparatives was 2.1 eV.

TABLE 1

| | | Eg(T) of | Luminous | Time until |
|---|---|---|---|---|
| | | Compound | Efficiency | Half-life |
| | Compound | (eV) | (cd/A) | (hrs) |
| Example 1 | (A-1) | 2.43 | 8.7 | 3400 |
| Example 2 | (A-6) | 2.35 | 6.9 | 1133 |
| Example 3 | (E-6) | 2.25 | 6.1 | 884 |
| Comparative 1 | (G-1) | 0.8 | 1.1 | 10 |
| Comparative 2 | (G-2) | 1.22 | 1.4 | 30 |
| Comparative 3 | (G-3) | 2.05 | 2.3 | 45 |
| Comparative 4 | (G-4) | 1.68 | 1.9 | 32 |
| Comparative 5 | (G-5) | 2.08 | 2.8 | 40 |

As is apparent from Table 1, it has been demonstrated that the organic EL device according to each of Examples 1 to 3 of the invention is excellent in luminous efficiency and has a significantly long lifetime.

In contrast, it has been found out that the organic EL device according to each of Comparatives 1 and 5 exhibits low luminous efficiency and has a short lifetime.

The organic EL device according to the exemplary embodiment of the invention can exhibit improved luminous efficiency because the triplet energy of the organic compound represented by the formula (1) or (2) and the triplet energy of the phosphorescent dopant are well-balanced. Additionally, the organic EL device can exhibit a longer lifetime than a conventional phosphorescent organic EL device because a molecule represented by the formula (1) or (2) contains no nitrogen atom or the like in the central skeleton thereof and employs specific partial structure and bonding pattern, which results in high tolerance against holes and electrons.

### INDUSTRIAL APPLICABILITY

The invention is applicable as a phosphorescent organic EL device having high efficiency and long lifetime.

### EXPLANATION OF CODES

1 organic electroluminescence device
2 substrate
3 anode
4 cathode
5 phosphorescent-emitting layer
6 hole injecting/transporting layer
7 electron injecting/transporting layer
10 organic thin-film layer

1. An organic electroluminescence device comprising:
a cathode;
an anode; and
a single-layered or multilayered organic thin-film layer situated between the cathode and the anode,
wherein
at least one layer forming the organic thin-film layer comprises an organic compound represented by formula (1): 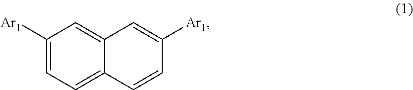
at least one layer forming the organic thin-film layer comprises a phosphorescent material,
a triplet energy Eg(T) of the organic compound represented by formula (1) is larger than a triplet energy Eg(T) of the phosphorescent material,
Ar₁ is a fused aromatic hydrocarbon ring, optionally substituted with a substituent and selected from the group consisting of a benzophenanthrene ring, a dibenzophenanthrene ring, a chrysene ring, a benzochrysene ring, a dibenzochrysene ring, a fluoranthene ring, a benzofluoranthene ring, a triphenylene ring, a benzotriphenylene ring, a dibenzotriphenylene ring, a picene ring, a benzopicene ring and a dibenzopicene ring, and
the substituent is a halogen atom, an alkoxy group, an aryloxy group, a cyano group, an arylsilyl group, an alkylsilyl group, an alkylarylsilyl group, an alkyl group, a haloalkyl group, an arylamino group or a heterocyclic group.

2. An organic electroluminescence device₁ comprising:
a cathode;
an anode; and
a single-layered or multilayered organic thin-film layer situated between the cathode and the anode,
wherein
at least one layer forming the organic thin-film layer comprises an organic compound represented by formula (2): 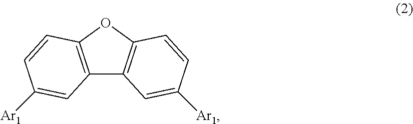
at least one layer forming the organic thin-film layer comprises a phosphorescent material,
a triplet energy Eg(T) of the organic compound represented by the formula (2) is larger than a triplet energy Eg(T) of the phosphorescent material,
Ar₁ is a fused aromatic hydrocarbon ring, optionally substituted with a substituent, and is selected from the group consisting of a benzophenanthrene ring, a dibenzophenanthrene ring, a chrysene ring, a benzochrysene ring, a dibenzochrysene ring, a fluoranthene ring, a benzofluoranthene ring, a triphenylene ring, a benzotriphenylene ring, a dibenzotriphenylene ring, a picene ring, a benzopicene ring and a dibenzopicene ring, and
the substituent is a halogen atom, an alkoxy group, an aryloxy group, a cyano group, an arylsilyl group, an alkylsilyl group, an alkylarylsilyl group, an alkyl group, a haloalkyl group, an arylamino group or a heterocyclic group.

3. The organic electroluminescence device according to claim 1, wherein the Arᵢ is one of a benzo[c]phenanthrene ring, optionally substituted with the substituent, and a benzo[g]chrysene ring, optionally substituted with the substituent.

4. The organic electroluminescence device according to claim 3, wherein the Ar₁ is one of a 5-benzo[c]phenanthrenyl group, optionally substituted with the substituent, a 6-benzo[c]phenanthrenyl group, optionally substituted with the substituent, and a 10-benzo[g]chrysenyl group, optionally substituted with the substituent.

5. The organic electroluminescence device according to claim 1, wherein the triplet energy Eg(T) of the organic compound represented by formula (1) is in a range of 2.2 eV to 2.7 eV.

6. The organic electroluminescence device according to claim 1, wherein at least one layer forming the organic thin-film layer comprises the organic compound represented by the formula (1) and the phosphorescent material.

7. The organic electroluminescence device according to claim 1, wherein at least one layer forming the organic thin-film layer functions as an emitting layer.

8. The organic electroluminescence device according to claim 1, wherein
the phosphorescent material comprises a metal complex, and
the metal complex comprises:
a metal atom selected from the group consisting of Ir, Pt, Os, Au, Re and Ru; and
a ligand.

9. The organic electroluminescence device according to claim 8, wherein the metal complex has an ortho-metal bond of the ligand and the metal atom.

10. The organic electroluminescence device according to claim 1, wherein at least one of the phosphorescent material contained in the organic thin-film layer emits light having a maximum emission wavelength of 600 nm to 720 nm.

11. The organic electroluminescence device according to claim 1, further comprising an electron transporting layer and an electron injecting layer situated between the cathode and the emitting layer, wherein
the electron transporting layer or the electron injecting layer comprises a heterocyclic compound comprising a nitrogen-containing six-membered or five-membered ring skeleton.

12. The organic electroluminescence device according to claim 1, further comprising a reduction-causing dopant situated at an interfacial region between the cathode and the organic thin-film layer.

13. The organic electroluminescence device according to claim 2, wherein the Ar₁ is one of a benzo[c]phenanthrene ring, optionally substituted with the substituent, and a benzo[g]chrysene ring, optionally substituted with the substituent.

14. The organic electroluminescence device according to claim 13, wherein the Ar₁ is one of a 5-benzo[c]phenanthrenyl group, optionally substituted with the substituent, a 6-benzo[c]phenanthrenyl group, optionally substituted with the substituent, and a 10-benzo[g]chrysenyl group, optionally substituted with the substituent.

15. The organic electroluminescence device according to claim 2, wherein the triplet energy Eg(T) of the organic compound represented by the formula (2) is in a range of 2.2 eV to 2.7 eV.

16. The organic electroluminescence device according to claim 2, wherein at least one layer forming the organic thin-film layer comprises the organic compound represented by formula (2) and the phosphorescent material.

17. The organic electroluminescence device according to claim 2, wherein at least one layer forming the organic thin-film layer functions as an emitting layer.

18. The organic electroluminescence device according to claim 2, wherein
the phosphorescent material comprises a metal complex, and
the metal complex comprises:
a metal atom selected from the group consisting of Ir, Pt, Os, Au, Re and Ru; and
a ligand.

19. The organic electroluminescence device according to claim 18, wherein the metal complex has an ortho-metal bond of the ligand and the metal atom.

20. The organic electroluminescence device according to claim 2, wherein at least one of the phosphorescent material contained in the organic thin-film layer emits light having a maximum emission wavelength of 600 nm to 720 nm.

21. The organic electroluminescence device according to claim 2, further comprising an electron transporting layer and an electron injecting layer situated the cathode and the emitting layer, wherein
the electron transporting layer or the electron injecting layer comprises a heterocyclic compound comprising a nitrogen-containing six-membered or five-membered ring skeleton.

22. The organic electroluminescence device according to claim 2, further comprising a reduction-causing dopant situated at an interfacial region between the cathode and the organic thin-film layer.
